(19) United States
(12) Patent Application Publication
(10) Pub. No.: US 2007/0195576 A1
(43) Pub. Date: Aug. 23, 2007

(54) Organic compound having functional groups different in elimination reactivity at both terminals, organic thin film, organic device and method of producing the same

(75) Inventors: Hiroshi Imada, Tenri-shi (JP); Hiroyuki Hanato, Nara-shi (JP); Toshihiro Tamura, Shiki-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/596,980

(22) PCT Filed: May 27, 2005
(86) PCT No.: PCT/JP05/09772

§ 371 Date: Nov. 20, 2006

(30) Foreign Application Priority Data
May 27, 2004 (JP) 2004-156971
Jul. 29, 2004 (JP) 2004-222175
Jul. 30, 2004 (JP) 2004-222763
May 26, 2005 (JP) 2005-154075

(51) Int. Cl. G11C 17/00; B05D 7/00; B05D 1/36; B32B 13/04; C07F 7/04

(52) U.S. Cl. 365/103; 427/407.1; 428/446; 365/104; 365/153; 546/14; 556/478

(57) ABSTRACT

Provided are a single monomolecular film uniform in film thickness and highly ordered in molecule alignment and its multilayer film, an organic compound allowing production of such films at high reproducibility, an organic device superior in electroconductive properties and a method of producing the same. An organic compound represented by Formula:
Si(A¹)(A²)(A³)-B—Si(A⁴)(A⁵)(A⁶)

(A¹ to A⁶ each represent a hydrogen atom, a halogen atom, an alkoxy group or an alkyl group and satisfy the relationship in elimination reactivity of: A¹ to A³>A⁴ to A⁶; and B represents a bivalent organic group), an organic thin film using the compound, and an organic device having the thin film; A method of producing an organic thin film and organic device, comprising a step of forming a single monomolecular film by allowing the silyl group having A¹ to A³ in the organic compound to react with the substrate surface; a step of removing unreacted organic compounds by using a non-aqueous solvent; and a step of forming an additional monomolecular film of the organic compound by using the unreacted silyl groups present on the film surface side of the monomolecular film obtained as the sites for adsorption reaction.

### TECHNICAL FIELD

The present invention relates to an organic compound having functional groups different in elimination reactivity at both terminals, an organic thin film, an organic device, and a method of producing the same.

### BACKGROUND ART

Inorganic materials such as a silicon crystal have been used in many semiconductor devices. However, in the trend toward miniaturization of devices, inorganic materials, which cause crystal defects and thus have adverse effects on device properties, have restriction in microfabrication.

Recently, research and development on semiconductors using an organic compound (organic semiconductor) are in progress and the results have been reported, because they are simpler in production and easier in processing than semiconductors of inorganic material and compatible with expansion in size of device, and allows cost reduction by mass production, and also because it is possible to prepare organic compounds with more functions than inorganic materials.

An organic compound becomes crystalline or amorphous, depending on its chemical structure and processing condition. When an organic compound is used for a semiconductor device, it is needed to select a material suitable for obtaining desirable properties. A device demanding high carrier mobility such as a transistor demands high crystallinity of the organic compound film. It is quite difficult to obtain 100% perfect crystal with a polymeric material, which has variation in molecular weight, and, among organic compounds, a low-molecular weight organic compound is normally used for such a device. For miniaturization and improvement in quantum effect of device, the organic compound film is preferably highly crystallized.

In an organic semiconductor device, carriers are obtained by injection of the carriers from the interface with a contact electrode material, if the organic material is not processed, for example by doping. For improvement in the carrier-injecting efficiency, an organic compound in contact with an electrode should have an ionization potential similar to that of the metal electrode, which restricts the kind of the organic compound used. Thus, an organic thin film formed with a laminate film containing a buffer layer such as a carrier-injecting layer is most preferably formed on the electrode and between electrodes.

It is known that, among organic compounds, organic compounds containing a π-electron-conjugated molecule when used are effective in producing a TFT having higher mobility. A typical example of the organic compound reported so far is pentacene (for example, Nonpatent Literature 1). The literature discloses that a TFT of an organic semiconductor layer formed by using pentacene has a field-effect mobility of 1.5 cm²/Vs and that it is possible thus to form a TFT having a mobility higher than that of amorphous silicon.

However, production of the organic compound semiconductor layer having a field-effect mobility higher than that of amorphous silicon described above demands a vacuum process such as resistance-heating vapor deposition or molecular-beam vapor deposition, making the production process more complicated, and a desirable crystalline film can be only prepared under a particular condition. In addition, the organic compound film is adsorbed on the substrate only physically, raising a problem that the adsorption strength of the film to the substrate is weak and the film is easily exfoliated. Further, the substrate for film formation is normally, previously processed, for example, by rubbing, for control of orientation of the organic compound molecules in a film to some extent, but there is no report yet that it is possible to control the compatibility and orientation of the compound molecules physically adsorbed at the interface between the organic compound and the substrate.

On the other hand, self-structured films of organic compound, which are easily produced, are attracting attention, and use of such a film is studied intensively, from the viewpoints of the regularity and crystallinity of film, which have a great influence on the field-effect mobility and are typical indicators of the TFT characteristics.

The self-structured film is a film in which part of an organic compound is bound to the functional group on the substrate surface, and also a film having extremely fewer defects and high order, i.e., crystallinity. The self-structured film can be formed on a substrate easily, because the production method is quite simple. Normally known as the self-structured films are a thiol film formed on a gold substrate and a silicon compound film formed on a substrate (such as a silicon substrate) having hydroxyl group protruded on the surface by hydrophilizing treatment. In particular, silicon compound films are attracting attention, because they have high durability. The silicon compound films have been used as a water-repellent coating film, and are formed by using a silane-coupling agent having an alkyl or fluoroalkyl group higher in water-repellent efficiency as its organic functional group.

However, the electric conductivity of the self-structured film is determined by the organic functional group in the silicon compound contained in film, but there is no commercially available silane-coupling agent containing a π-electron-conjugated molecule in the organic functional group, and thus, it is difficult to provide the self-structured film with conductivity. Accordingly, there exists a need for a silicon compound suitable for the device such as a TFT containing a π-electron-conjugated molecule in its organic functional group.

Proposed as such a silicon compound is a compound having a thiophene ring at the molecular terminal as its functional group in which the thiophene ring is bound to Si via a straight-chain hydrocarbon group (for example, Patent Document 1). Alternatively, a polyacetylene film prepared by forming a —Si—O— network on a substrate by chemical adsorption and polymerizing the region of the acetylene group was also proposed (for example, Patent Document 2). Yet alternatively, proposed was an organic device using, as its semiconductor layer, a conductive thin film that is prepared by using a silicon compound, in which a straight-chain hydrocarbon group is bound to the 2 and 5 positions of a thiophene ring and the terminal of the straight-chain hydrocarbon is bound to a silanol group, as the organic material, forming a self-structured film thereof on a substrate, and polymerizing the molecules for example by electrolytic polymerization (for example, Patent Document 3). Yet alternatively, a field effect transistor prepared by using a semiconductor thin film of a silicon compound containing polythiophene, the thiophene ring of which is bound to a silanol group, as the principal component was proposed (for example, Patent Document 4).

Although it is possible to produce a self-structured film chemically adsorbed on a substrate with the compound proposed above, it was not always possible to produce a film higher in order and crystallinity and having favorable electroconductive properties for use in electronic devices such as a TFT. Further, use of the compound proposed above as a semiconductor layer of organic TFT raised a problem of increase in off current. It seems that the proposed compound has bonds both in the molecular direction and in the direction perpendicular thereto.

For obtaining high order, i.e., high crystallinity, there should be high intermolecular attractive interaction in effect. The intermolecular force includes an attractive factor and a repulsive factor, and the former is inversely proportional to the intermolecular distance to the sixth, while the latter to the intermolecular distance to the 12th. Thus, the total intermolecular force, the sum of the attractive and repulsive factors, has the relationship shown in FIG. 10. The minimum point in FIG. 10 (region indicated by arrow in Figure) is the intermolecular distance at which the intermolecular force is most attractive in combination of the attractive and repulsive factors. Thus, it is important to make the intermolecular distance as close as possible to the minimum point, for obtaining higher crystallinity. Accordingly in a vacuum process such as resistance-heating vapor deposition or molecular-beam vapor deposition, high order, i.e., high crystallinity, is obtained by controlling the intermolecular interaction among π-electron-conjugated molecules properly, only under a particular condition. Only a crystalline film formed under such intermolecular interaction can express high electroconductive properties.

On the other hand, although the compound above may be chemically adsorbed on a substrate by forming a Si—O—Si two-dimensional network and have order by intermolecular interaction among particular long-chain alkyl groups, there was a problem that the interaction between molecules is weaker and the length of the π-electron conjugation system essential for electric conductivity is very small, because the functional group, a thiophene molecule, contributes only to π-electron conjugation system. Even if the number of the functional groups, thiophene molecules, is increased, it is difficult to make the film-ordering factor have harmonized intermolecular interactions with the long-chain alkyl and thiophene groups.

As for electroconductive properties, such a compound had a problem that the HOMO-LUMO energy gap of the functional group, a thiophene molecule, was greater, prohibiting the compound to show sufficient carrier mobility even if it is used in TFT as an organic semiconductor layer.

In addition, when a multilayered monomolecular film (multilayer film) is formed on a substrate by chemical adsorption by using a terminal silyl group-containing silicon compound, there was a problem in the reactivity of the terminal silyl group. An example of the method of forming a multilayer film by chemical adsorption reported in the past is described in Patent Document 5. In the patent document, an alkylsilane compound having trichlorosilyl groups at both terminals was used as the compound that is bound to the substrate in adsorption reaction. Specifically, disclosed is a method of forming a multilayer film including the steps of forming a monomolecular film on a substrate surface and forming an additional monomolecular film thereon by using the trichlorosilyl groups remaining unreacted at the air interface-sided surface of the film as the adsorption reaction sites.

However, the trichlorosilyl group is known to have extremely high reactivity due to its chlorine atoms in elimination reaction. When it has two trichlorosilyl groups at both terminals, the trichlorosilyl group at any terminal may be hydrolyzed during formation of monomolecular film. As a result, the silicon compounds are adsorbed on the substrate and, at the same time, dimerize or trimerize by using the terminal groups at the unreacted side as the next adsorption points. Thus, it was difficult to form a multilayer unimolecular film uniform in film thickness and higher in crystal-orientation order, at high reproducibility by chemical adsorption with the conventional compound. A device produced by using a multilayer unimolecular film uneven in film thickness and lower in crystal-orientation order shows deterioration in performance by trapping of the carrier between multilayer films.
Nonpatent Literature 1: IEEE Electron Device Lett., 18, 606-608 (1997)
Patent Document 1: Japanese Patent No. 2889768
Patent Document 2: Japanese Examined Patent Publication No. Hei6-27140
Patent Document 3: Japanese Patent No. 2507153
Patent Document 4: Japanese Patent No. 2725587
Patent Document 5: Japanese Patent No. 3292205

### DISCLOSURE OF INVENTION

### TECHNICAL PROBLEMS TO BE SOLVED

An object of the present invention is to provide a single monomolecular film uniform in film thickness and highly ordered in molecular orientation, the multilayer film thereof, an organic compound allowing production of such films at high reproducibility, and a method of producing the same.

Another object of the present invention is to provide an organic thin film easily formed by a particularly simple production method, adsorbed on the substrate surface tightly, preventing physical exfoliation, and superior in orientation, crystallinity, and electroconductive properties, an organic compound allowing production of the film at high reproducibility, and a method of producing the same.

Yet another object of the present invention is to provide an organic device easily produced by a simple method and superior in electroconductive properties, and a method of producing the same.

### MEANS TO SOLVE THE PROBLEMS

The present invention relates to an organic compound represented by General Formula (I): 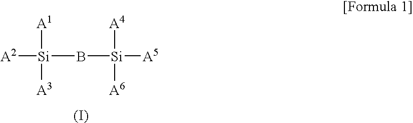
(wherein, A¹ to A⁶ each independently represent a hydrogen atom, a halogen atom, an alkoxy group having 1 to 10 carbon atoms, or an alkyl group having 1 to 18 carbon atoms; A¹ to A⁶ satisfy the relationship in elimination reactivity of A¹ to A³>A⁴ to A⁶; and B represents a bivalent organic group), and in particular, to an organic compound represented by General Formula (I), wherein the organic group B is a π-electron-conjugated bivalent organic group.

The present invention also relates to a method of producing the organic compound above, comprising;

allowing a compound represented by (Formula):
H—B—MgX (2)
(wherein, B represents a bivalent organic group; and X represents a halogen atom) to react with a compound represented by (Formula):
Y¹—Si(A¹)(A²)(A³) (3)
(wherein, Y¹ represents a halogen atom; and A¹ to A³ each independently represent a hydrogen atom, a halogen atom, an alkoxy group having 1 to 10 carbon atoms, or an alkyl group having 1 to 18 carbon atoms) in order to form a compound represented by (Formula):
H—B—Si(A¹)(A²)(A³) (4);

preparing a compound represented by (Formula):
MgX—B—Si(A¹)(A²)(A³) (5)
by binding a halogen atom to the B group in the compound shown in Formula (4) and allowing the halogenated compound to react with magnesium or lithium metal in the presence of ethoxyethane or tetrahydrofuran (THF); and

allowing the product to react with a compound represented by (Formula):
Y²—Si(A⁴)(A⁵)(A⁶) (6)
(wherein, Y² represents a halogen atom; and A⁴ to A⁶ each independently represent a hydrogen atom, a halogen atom, an alkoxy group having 1 to 10 carbon atoms, or an alkyl group having 1 to 18 carbon atoms, and satisfy the relationship in elimination reactivity of A¹ to A³>A⁴ to A⁶).

The present invention also relates to a method of producing the organic compound, comprising;

forming a Grignard reagent from a compound represented by (Formula):
X¹—B—X² (8)
(wherein, B represents a bivalent organic group; and X¹ and X² each differently represents a halogen atom) by using a metal catalyst such as magnesium or lithium;

allowing the product to react with a compound represented by (Formula):
Y¹—Si(A¹)(A²)(A³) (3)
(wherein, Y¹ represents a halogen atom, and A¹ to A³ each independently represent a hydrogen atom, a halogen atom, an alkoxy group having 1 to 10 carbon atoms, or an alkyl group having 1 to 18 carbon atoms) in order to prepare a Grignard reagent represented by the following (Formula):
Si(A¹)(A²)(A³)-B—MgX² (9); and then,

allowing a compound represented by (Formula):
Y²—Si(A⁴)(A⁵)(A⁶) (6)
(wherein, Y² represents a halogen atom, and A⁴ to A⁶ each independently represent a hydrogen atom, a halogen atom, an alkoxy group having 1 to 10 carbon atoms, or an alkyl group having 1 to 18 carbon atoms and satisfy the relationship in elimination reactivity of A¹ to A³>A⁴ to A⁶) to react with the compound represented by (Formula 9).

The present invention also relates to an organic thin film formed by using the organic compound.

The present invention relates to a method of producing an organic thin film having a multilayer unimolecular film structure, comprising

(1) a step of forming a single monomolecular film having a monomolecular layer directly adsorbed to a substrate by allowing the silyl group having A¹ to A³ in the organic compound to react with the substrate surface;

(2) a step of removing unreacted organic compounds by using a non-aqueous solvent; and

(3) a step of forming an additional monomolecular film of the organic compound by using the unreacted silyl groups, which are present on the film surface side of the monomolecular film obtained, as the sites for adsorption reaction.

The present invention also relates to an organic device having the organic thin film.

The present invention also relates to a method of producing an organic device, comprising forming an organic thin film by the method of producing an organic thin film above.

In the present specification, the single monomolecular film means an organic thin film having a single layer of monomolecular film.

The multilayer unimolecular film means an organic thin film having two or more layers of monomolecular films formed integrally (laminated).

### EFFECT OF THE INVENTION

The organic compound according to the present invention provides a film highly stabilized and highly crystallized, because the film is adsorbed chemically on the substrate by the two-dimensional Si—O—Si network formed among the compound molecules and a short-distance force needed for crystallization of film, i.e., intermolecular interaction among molecules, exerts influence efficiently. Thus, the compound gives a film more tightly adsorbed on the substrate surface than the film formed on the substrate by physical adsorption, and prevents physical exfoliation of the film.

It is also possible to form an organic thin film higher in order (crystallinity) by the intermolecular interaction between the network derived from the organic compound and π-conjugated molecules, because the network derived from the organic compound constituting the organic thin film is bound directly to the organic groups. In this way, the carrier moves more smoothly by hopping conduction in the directions in parallel with and perpendicular to the molecular plane. Because the film has high conductivity also in the molecular axial direction, the film may be used widely as a conductive material not only for organic thin-film transistor material but also for solar cell, fuel cell, sensor, and the like.

In addition, such a compound can be produced easily.

It is also possible to perform adsorption on the substrate and on the film surface stepwise, selectively at high reproducibility, by varying the elimination reactivity of the groups bound to the silicon between the silyl groups that an organic compound has at both terminals, as shown in General Formula (I). Thus, the present invention provides a multilayer film more uniform in film shape and molecular orientation, at higher reproducibility than traditional methods. In other words, the present invention provides an organic thin film higher in molecule orientation in which the molecules are oriented orderly not only in the film direction but also in the film thickness direction.

When such an organic thin film is produced as a multilayer unimolecular film, the organic thin film has electrical properties different in the film thickness direction, according to the electrical properties of the constituent monomolecular layers of several nm in thickness. As a result, it is possible to control the carrier mobility efficiency, charge injection efficiency on the electrode interface, and others. In addition, the film can be applied to photo/temperature/gas sensor devices allowing high-density recording and high-speed response and/or at high sensitivity.

Further, the organic compound according to the present invention, which is self-structuring, does not demand production of an organic thin film highly crystallized and oriented under vacuum, and allows production thereof in air, which means that the production is simpler and more cost-effective, and thus, the method is advantageous as a commercial process.

It is also possible to give anisotropy in electrical properties not only in the film thickness direction but also in the film direction, by performing pretreatment, hydrophilization, of substrate in patterning. It is thus possible to produce an organic thin film different in electrical properties in the pseudo-three-dimensional directions, which is applicable to next-generation electric devices.

It is possible to orient materials different in conductivity, thermal sensitivity, or photosensitivity at the several nm order in the multilayer unimolecular film in the direction vertical to the substrate, and thus, such a multilayer unimolecular film is applicable, for example, to the fields of high-density recording, high-speed response switch, and fine-region conductivity, organic electroluminescence (EL) elements having a hetero structure at the nm-thickness order containing layers such as electron and positive-hole injecting, electron and positive-hole transporting, and light-emitting layers, and photoelectric conversion elements for use in a solar cell, and others.

### BRIEF DESCRIPTION OF THE DRAWINGS

FIG. 1 is a schematic view illustrating the molecular orientation of a monomolecular film formed on a substrate in the present invention.

FIG. 2 is a schematic view illustrating the monomolecular film after the ethoxy groups in the unreacted silyl groups present on the film surface side in FIG. 1 are replaced with hydroxyl groups during formation of a multilayer unimolecular film.

FIG. 3 is a schematic view illustrating the molecular orientation of a bilayer unimolecular film having an additional monomolecular film formed on the monomolecular film shown in FIG. 2.

FIG. 4 is a schematic view for explanation of the electric conductivity measurement by in-plane electrical AFM measurement.

FIGS. 5(A) and (B) are schematic views illustrating a multilayer unimolecular film formed by using two kinds of organic compounds (I).

FIGS. 6(A) to (C) are schematic configuration views illustrating an organic thin-film transistor according to the present invention.

FIG. 7 is a schematic configuration view illustrating an organic photoelectric conversion element according to the present invention.

FIG. 8 is a schematic configuration view illustrating an organic EL element according to the present invention.

FIG. 9 is a schematic sectional view illustrating an organic thin-film transistor prepared in Example.

FIG. 10 is a chart for explaining the relationship between intermolecular distance and intermolecular force.

### EXPLANATION OF REFERENCES

1: Hydrophilized substrate,

10: SPM device-based piezoelectric element,

11: Cantilever,

12: Monomolecular film or multilayer unimolecular film,

13: Gold/chromium electrode,

14: Mica substrate,

15: Ammeter,

20: Semiconductor layer,

21: Source electrode,

22: Drain electrode,

23: Gate insulation film,

24: Gate electrode,

25: Silicon substrate,

31: Transparent electrode,

32: Counter electrode,

33: n-type photoconductive layer,

34: p-type photoconductive layer,

35: Organic layer,

41: Anode,

42: Cathode,

43: Light-emitting layer,

44: Positive hole-transporting layer,

45: Electron-transporting layer, and

48: Organic layer.

### BEST MODE FOR CARRYING OUT THE INVENTION

(Organic Compound)

The organic compound according to the present invention has functional groups different in elimination reactivity at both terminals of the molecule and is represented by the following General Formula (I):

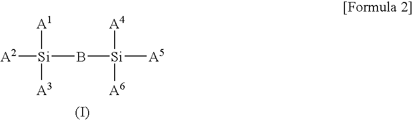

In General Formula (I), A¹ to A⁶ each independently represent a hydrogen atom, a halogen atom, an alkoxy group having 1 to 10 carbon atoms, or an alkyl group having 1 to 18 carbon atoms; and A¹ to A⁶ satisfy the relationship of A¹ to A³>A⁴ to A⁶ in elimination reactivity.

In the present invention, the elimination reactivity means “feasibility of a group being eliminated in water” and a high elimination reactivity means that the group is easily released (hydrolyzed) in water.

The relationship of A¹ to A³>A⁴ to A⁶ in elimination reactivity means that the reactivity of at least one of the groups A¹ to A³, preferably all of them, is higher than the highest reactivity of A⁴ to A⁶. A¹ to A³ may be the same as or different from each other, and A⁴ to A⁶ may also be the same as or different from each other, if the relationship is satisfied.

As described above, the organic compound according to the present invention has a silyl group having groups A⁴ to A⁶ relatively lower in elimination reactivity at one terminal and a silyl group having at least one of the groups A¹ to A³ higher in elimination reactivity than the A⁴ to A⁶ at the other terminal. Thus, by adjusting, for example, proton concentration in water, it is possible to control the reactivity of the two silyl groups of the organic compound according to the present invention separately, the absorption reaction of one silyl group onto a substrate or organic film surface, and the subsequent adsorption reaction by the other silyl group easily. As a result, it is possible to produce a single monomolecular film uniform in film thickness and highly ordered in molecular orientation and the multilayer film thereof at high reproducibility.

Examples of the halogen atoms for A¹ to A⁶ include fluorine, chlorine, bromine, and iodine atoms, and the like.

The alkoxy group has a carbon number of 1 to 10, preferably 1 to 6, and more preferably 1 to 4, from the viewpoint of the solubility and film-forming efficiency of the compound according to the present invention. Typical favorable examples of the alkoxy groups include methoxy, ethoxy, n- or 2-propoxy, n-, sec- or tert-butoxy, n-pentyloxy, n-hexyloxy group, and the like. An excessively large number of the methylene groups in alkoxy group results in aggregation and crystallization of the carbon chains, forming a kind of insulation layer, and consequently leading to deterioration in the properties of device.

The alkyl group has a carbon number of 1 to 18, preferably 1 to 10, and more preferably 1 to 6, from the viewpoint of the solubility and film-forming efficiency of the compound according to the present invention. Favorable typical examples of the alkyl groups include methyl, ethyl, n- or 2-propyl, n-, sec- or tert-butyl, n-pentyl, n-hexyl, n-heptyl, n-octyl, n-nonyl, n-decyl, and the like. An excessively large number of the methylene groups of alkyl group results in aggregation and crystallization of the carbon chains, forming a kind of insulation layer, and consequently leading to deterioration in the properties of device.

The elimination reactivity of the atoms or groups described above depends on the basicity of the atoms or groups. The elimination reactivity of a hydrocarbon group also depends on the number of methylene groups and its spatial structure. Thus, it is difficult to specify the order of the elimination reactivity for all atoms and groups, but the general order is as follows, when alkoxy and alkyl groups are regarded as one group.

First group: halogen atoms

Second group: alkoxy and alkyl groups

Third group: hydrogen atom

In the order above, the latter group is lower in elimination reactivity.

Specifically, among halogen atoms in the first group, the elimination reactivity declines in the order of iodine, bromine, and chlorine.

The elimination reactivity of the alkoxy and alkyl groups in the second group declines in the order of alkoxy and alkyl group when the carbon number is the same, but it is not possible to specify the order definitely when the carbon number is different, because the reactivity depends of the number of carbons and its spatial structure. As for the order in the reactivity of alkoxy or alkyl groups when the carbon number is different, a group having a larger number of carbon atoms is lower in reactivity. From the viewpoint of spatial structure, the elimination reactivity of alkoxy or alkyl group declines when the alkyl contained in the group is primary, secondary, and tertiary in that order.

The elimination reactivity of particular groups (for example, groups X and Y) can be determined by adding a silane compound containing the groups X and Y such as Si(X)₂ (Y)₂ into water, stirring the mixture for a certain period, and analyzing the hydrolysate of the silane compound. The group more substituted with hydroxyl group is the group relatively higher in elimination reactivity. If the groups X and Y are both substituted or not substituted with hydroxyl group, it is preferably to adjust the pH of water in such a way that one group is substituted with hydroxyl group.

The analytical method is not particularly limited, if it can show presence or absence of the X, Y, and hydroxyl groups, and examples thereof include mass spectrometry and chromatographic analysis.

Favorable combinations of A¹ to A³ and A⁴ to A⁶ in the organic compound according to the present invention will be shown below.

(1) A¹ to A³ each independently represent a halogen atom, preferably they are all chlorine or bromine atoms, in particular chlorine atoms; and

A⁴ to A⁶ each independently represent an alkoxy group, preferably they are all methoxy or ethoxy groups, in particular ethoxy groups.

(2) A¹ to A³ each independently represent a halogen atom, preferably they are all chlorine or bromine atoms, in particular chlorine atoms; and A⁴ to A⁶ each independently represent an alkyl group, preferably they are all methyl or ethyl groups, in particular ethyl groups.

(3) A¹ to A³ each independently represent an alkoxy group having 1 to 2 carbon atoms, preferably they are all methoxy or ethoxy groups, in particular methoxy groups; and

A⁴ to A⁶ each independently represent an alkoxy group having 3 to 4 carbon atoms, preferably they are all 2-propoxy or sec- or tert-butoxy groups, in particular tert-butoxy groups.

(4) A¹ to A³ each independently represent an alkoxy group having 1 to 2 carbon atoms, preferably they are all methoxy or ethoxy groups, in particular methoxy groups; and

A⁴ to A⁶ each independently represent an alkyl group having 3 to 4 carbon atoms, preferably they are all 2-propyl, or sec- or tert-butyl groups, in particular tert-butyl groups.

Among the combinations above, favorable are combinations (1) and (2), in particular combination (1).

Typical examples the compound according to the present invention satisfying the requirement of the combination (1) will be shown below. 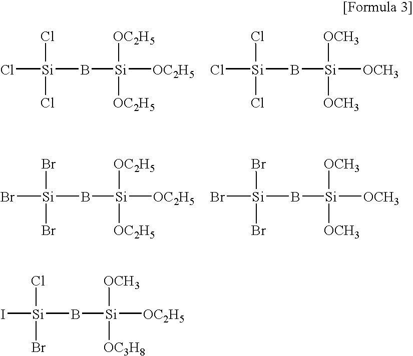
(wherein, B is the same as B in General Formula (I), as will be described below in detail).

Typical examples of the compound according to the present invention satisfying the requirement of the combination (2) will be shown below. 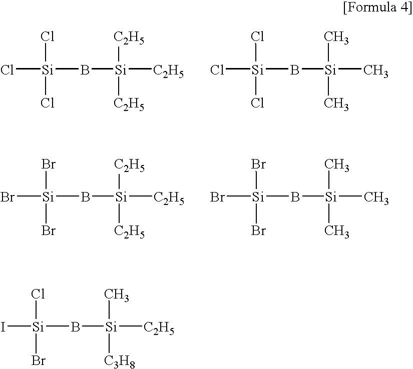
(wherein, B is the same as B in General Formula (I), as will be described below in detail).

Typical examples the compound according to the present invention satisfying the requirement of the combination (3) will be shown below. 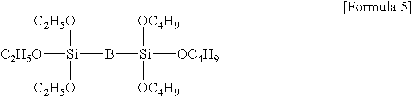
(wherein, B is the same as B in General Formula (I), as will be described below in detail).

In the present invention, the combination of A¹ to A³ and A⁴ to A⁶ is not limited, if the elimination reactivity thereof satisfies the relationship of A¹ to A³>A⁴ to A⁶.

In General Formula (I), B is not particularly limited, if it is a bivalent organic group, and may be, for example, a π-electron conjugated or non-conjugated group. Thus, B may be a π-electron-conjugated bivalent organic group b1 or a non-π-electron-conjugated bivalent organic group b2. When B is a π-electron-conjugated bivalent organic group b1, the resulting organic thin film shows superior electrical properties.

The π-electron-conjugated bivalent organic group b1 is a group derived from a molecule having a π-electron conjugated skeleton (π-electron-conjugated skeleton), for example, a residue of the molecule lacking two eliminated hydrogen atoms. The π-electron-conjugated skeleton is decided according to desired electrical properties, and may contain a heterocyclic ring and/or have a monocyclic or polycyclic structure. Examples of the π-electron-conjugated skeletons include aromatic skeletons, heterocyclic ring skeletons, unsaturated aliphatic skeletons, the composite skeletons thereof, and the like.

Examples of the π-electron-conjugated skeleton-containing molecules (π-electron-conjugated compounds) for the organic group b1 include monocyclic aromatic compounds, condensed aromatic compounds, monocyclic heterocyclic compounds, condensed heterocyclic compounds, unsaturated aliphatic compounds, and connected compounds thereof containing two or more compounds above bound to each other.

Examples of the monocyclic aromatic compounds include benzene, toluene, xylene, mesitylene, cumene, and the like.

Examples of the condensed aromatic compounds include naphthalene, anthracene, naphthacene, pentacene, hexacene, heptacene, octacene, nonacene, azulene, fluorene, pyrene, acenaphthene, perylene, anthraquinone, and the like. Typical examples thereof include the compounds represented by the following Formulae (α1) to (α3) (in Formula (α1), n is 0 to 10).

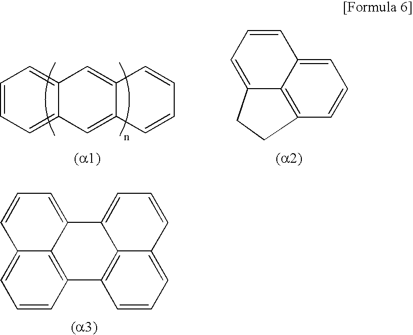

The compound represented by Formula (α1) is a compound having an acene skeleton, the compound represented by Formula (α2) is a compound having an acenaphthene skeleton; and the compound represented by Formula (α3) is a compound having a perylene skeleton. The number of the benzene rings for the compound having an acene skeleton represented by the Formula (α1) is preferably 2 to 12. Among them, compounds having a benzene ring number of 2 to 9 such as naphthalene, anthracene, tetracene, pentacene, hexacene, heptacene, octacene, and nonacene are particularly preferable, considering the number of synthetic steps and the yield of product. In Formula (α1) above, shown is a compound having benzene rings condensed linearly, but non-linearly condensed molecules such as phenanthrene, chrysene, picene, pentaphen, hexaphen, heptaphen, benzanthracene, dibenzophenanthrene, and anthranaphthacene are also included in the compound represented by Formula (α1).

Examples of the monocyclic heterocyclic compounds include furan, thiophene, pyridine, pyrimidine, oxazole, and the like.

Examples of the condensed heterocyclic compounds include condensation compounds between heteroatom-containing five- or six-membered rings such as thiophene, pyridine, or furan, and between a heteroatom-containing five-membered ring or six-membered ring and an aromatic ring. Typical examples thereof include indole, quinoline, acridine, benzofuran, and the like.

Examples of the unsaturated aliphatic compounds include alkenes such as ethylene, propylene, butylene, butene, and pentene; alkadienes such as propadiene, butadiene, pentadiene, and hexadiene; alkatrienes such as butatriene, pentatriene, hexatriene, heptatriene, and octatriene, and the like.

The connected compound is a compound in which two or more of compounds, in particular 2 to 8 compounds, selected from the group consisting of the monocyclic aromatic compounds, condensed aromatic compounds, monocyclic heterocyclic compounds, condensed heterocyclic compounds and unsaturated aliphatic compounds described above are bound to each other via single bonds. Preferably, the connected compound is the compound having two or more, in particular 2 to 8, monocyclic aromatic compounds and/or monocyclic heterocyclic compounds bound to each other.

The compound having two or more monocyclic aromatic compounds and/or monocyclic heterocyclic compounds bound to each other is, for example, a compound having two or more benzenes and/or thiophenes bound to each other. The compound preferably has 2 to 10 benzenes and/or thiophenes bound to each other. The total number of benzenes and/or thiophenes is more preferably 2 to 8, considering the yield, cost, and mass productivity.

The compounds constituting the connected compound may be bound to each other in the branched form, but are preferably bound linearly. At least part of the compounds constituting the connected compound may be the same as each other, or alternatively, all of them are different from each other. In the connected compound, different compounds may be bound to each other orderly or randomly. In addition, the binding sites on the compounds constituting the connected compound may be 2,5-sites, 3,4-sites, 2,3-sites, 2,4-sites, or the like, but are preferably 2,5-sites, when the constituent compound molecule is thiophene. The binding sites may be 1,4-sites, 1,2-sites, 1,3-sites or the like, but are preferably 1,4-sites, when it is benzene.

Typical examples of the compounds having two or more bound monocyclic aromatic compounds include the phenylenes represented by the following Formula (i);

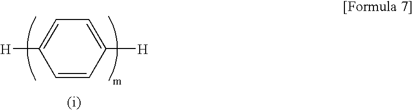

(wherein, m is an integer of 2 to 30, preferably an integer of 2 to 8). The phenylenes may have substituent groups such as alkyl groups, aryl groups, and halogen atoms. The phenylene compounds in the present description include the compound of Formula (i) wherein m is 1.

Typical examples of the compounds having two or more bound monocyclic heterocyclic compounds include the thiophenes represented by the following Formula (ii); 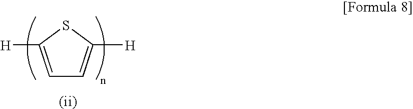
(wherein, n is an integer of 2 to 30, preferably an integer of 2 to 8). The thiophenes may have substituent groups such as alkyl groups, aryl groups, and halogen atoms. The thiophene compounds in the present description include the compound of Formula (ii) wherein n is 1.

Typical examples of the compounds having two or more bound monocyclic aromatic and/or monocyclic heterocyclic compounds include compounds derived from biphenyl, bithiophenyl, terphenyl (compound of Formula iii), terthienyl (compound of Formula iv), quarterphenyl, quarterthiophene, quinquephenyl, quinquethiophene, hexiphenyl, hexithiophene, thienyl-oligophenylene (see compound of Formula v), phenyl-oligooligo thienylene (see compound of Formula vi), and block co-oligomers (see compound in Formula vii or viii).

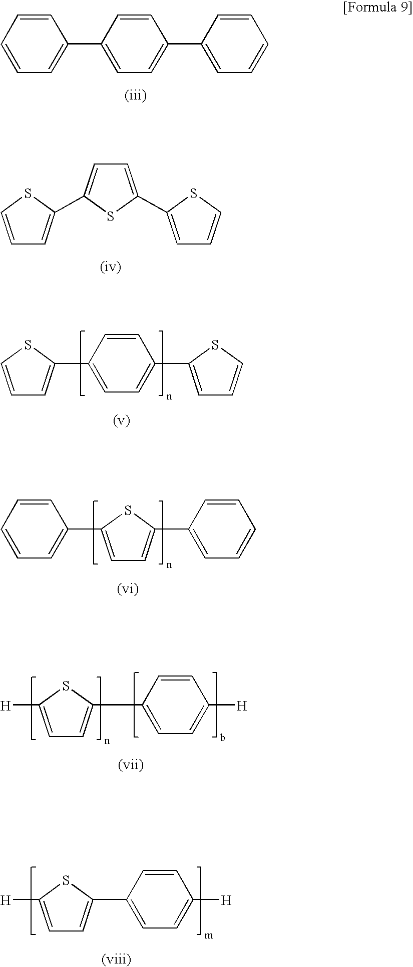

(in Formulae (v) and (vi), n is an integer of 1 to 8; in Formula (vii), a+b is an integer of 2 to 10; and in Formula (viii), m is an integer of 1 to 8.)

The organic group b1 derived from the π-electron-conjugated compound may have functional groups at any positions. Typical functional groups include a hydroxyl group, substituted or unsubstituted amino groups, a nitro group, a cyano group, substituted or unsubstituted alkyl groups, substituted or unsubstituted alkenyl groups, substituted or unsubstituted cycloalkyl groups, substituted or unsubstituted alkoxy groups, substituted or unsubstituted aromatic hydrocarbon groups, substituted or unsubstituted heterocyclic aromatic groups, substituted or unsubstituted aralkyl groups, substituted or unsubstituted aryloxy groups, substituted or unsubstituted alkoxycarbonyl groups, a carboxyl group, ester groups, and the like. Among these functional groups, functional groups that do not inhibit crystallization of the organic thin film by steric hindrance are preferable, and thus, among the functional groups above, straight-chain alkyl groups having 1 to 30 carbon atoms are particularly preferable.

Non-π-electron-conjugated bivalent organic group b2 is a group derived from a molecule having a non-π-electron-conjugated skeleton (non-π-electron-conjugated skeleton), for example, a residue of the molecule lacking two eliminated hydrogen atoms, and may be substituted with halogen atoms. The non-π-electron-conjugated skeleton is, for example, a material having a saturated aliphatic skeleton.

Examples of the non-π-electron-conjugated skeleton-containing molecules for the organic group b2 include saturated aliphatic compounds, and the like.

Examples of the saturated aliphatic compounds include alkanes and the like. Favorable typical examples of the alkanes include straight-chain alkane having 1 to 30 carbon atoms, particularly 1 to 20 carbon atoms, and the like.

Examples of the halogen atoms to be substituted when the non-π-electron-conjugated skeleton-containing molecule forms the organic group b2 include fluorine, chlorine, bromine, and iodine atoms, and the like.

Among the π-electron-conjugated skeleton-containing molecules and non-π-electron-conjugated skeleton-containing molecules, the organic group B is preferably a group derived from a monocyclic aromatic compound (in particular, benzene), a monocyclic heterocyclic compound (in particular, thiophene), a condensed aromatic compound (in particular, naphthalene, acene, pyrene, or perylene), a saturated aliphatic compound (in particular, alkane) or a compound having two or more, particulary 2 to 8, of the compounds above bound to each other, from the viewpoint of the molecular crystallinity of organic thin film.

The organic group B is preferably a group derived from a monocyclic aromatic compound, a condensed aromatic compound, a monocyclic heterocyclic compound, a condensed heterocyclic compound, an unsaturated aliphatic compound, or a compound having two or more, particularly 2 to 8, of compounds above bound to each other, from the viewpoint of the conductivity of organic thin film.

More preferably from the viewpoint of the conductivity of organic thin film, the organic group B is a group derived from a monocyclic aromatic compound (in particular, benzene), a monocyclic heterocyclic compound (in particular, thiophene), a condensed aromatic compound (in particular, naphthalene, acene, pyrene, or perylene), an unsaturated aliphatic compound (in particular, alkene, alkadiene, or alkatriene), or a compound having two or more, particulary 2 to 8, of the compounds above bound to each other.

Most preferably from the viewpoint of the conductivity of organic thin film, the organic group B is a group derived from a monocyclic aromatic compound (in particular, benzene), a monocyclic heterocyclic compound (in particular, thiophene) or a compound having two or more, particularly 2 to 8, of the compounds above bound to each other, or a condensed aromatic compound (in particular, acene, pyrene, or perylene). Particularly preferable organic groups B include groups derived from thiophene compound derivatives, phenylene compound derivatives, ethylene derivatives, naphthalene derivatives, anthracene derivatives, tetracene derivatives, pyrene derivatives, and perylene derivatives.

Typical favorable examples of the compounds according to the present invention are shown below.

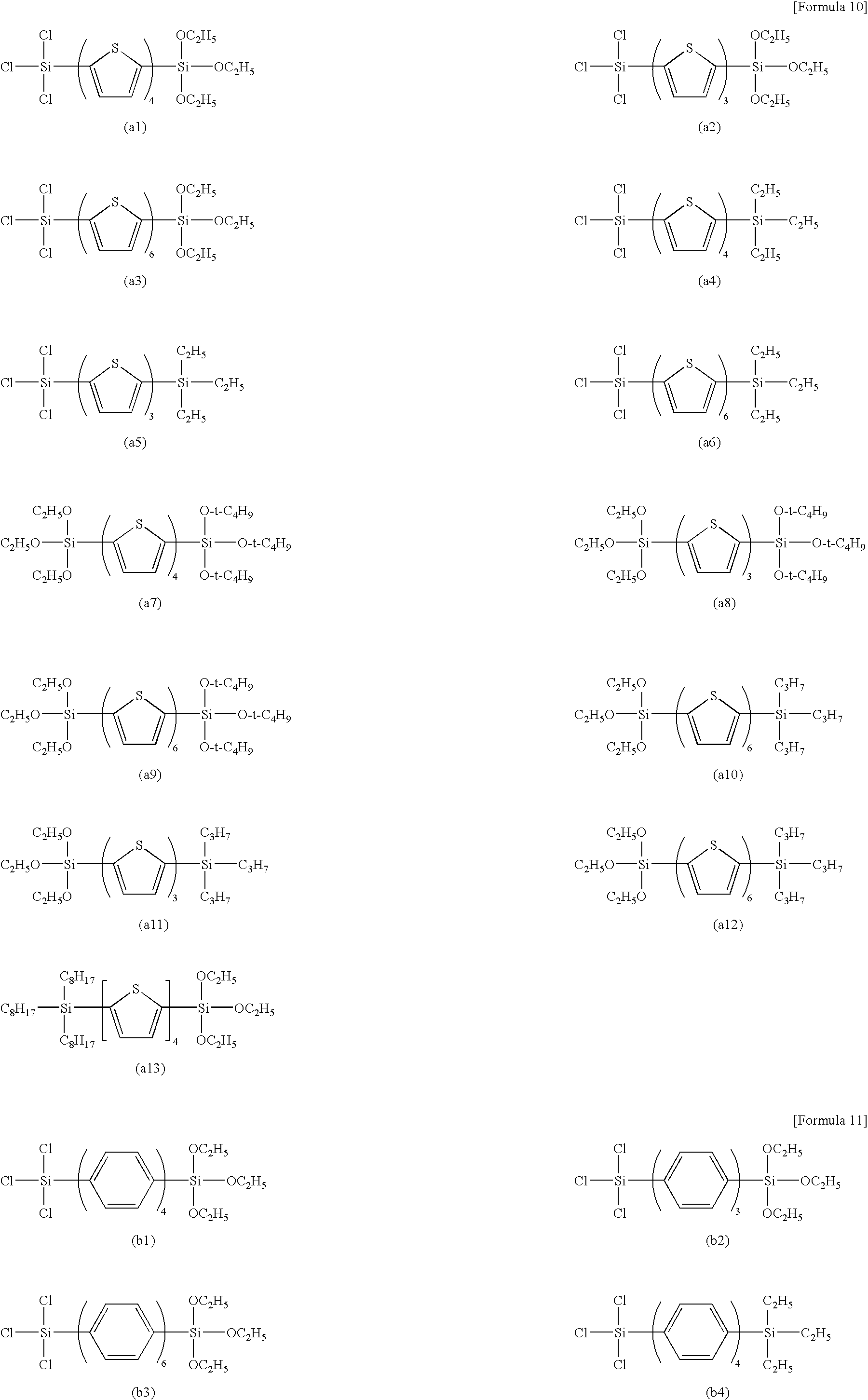

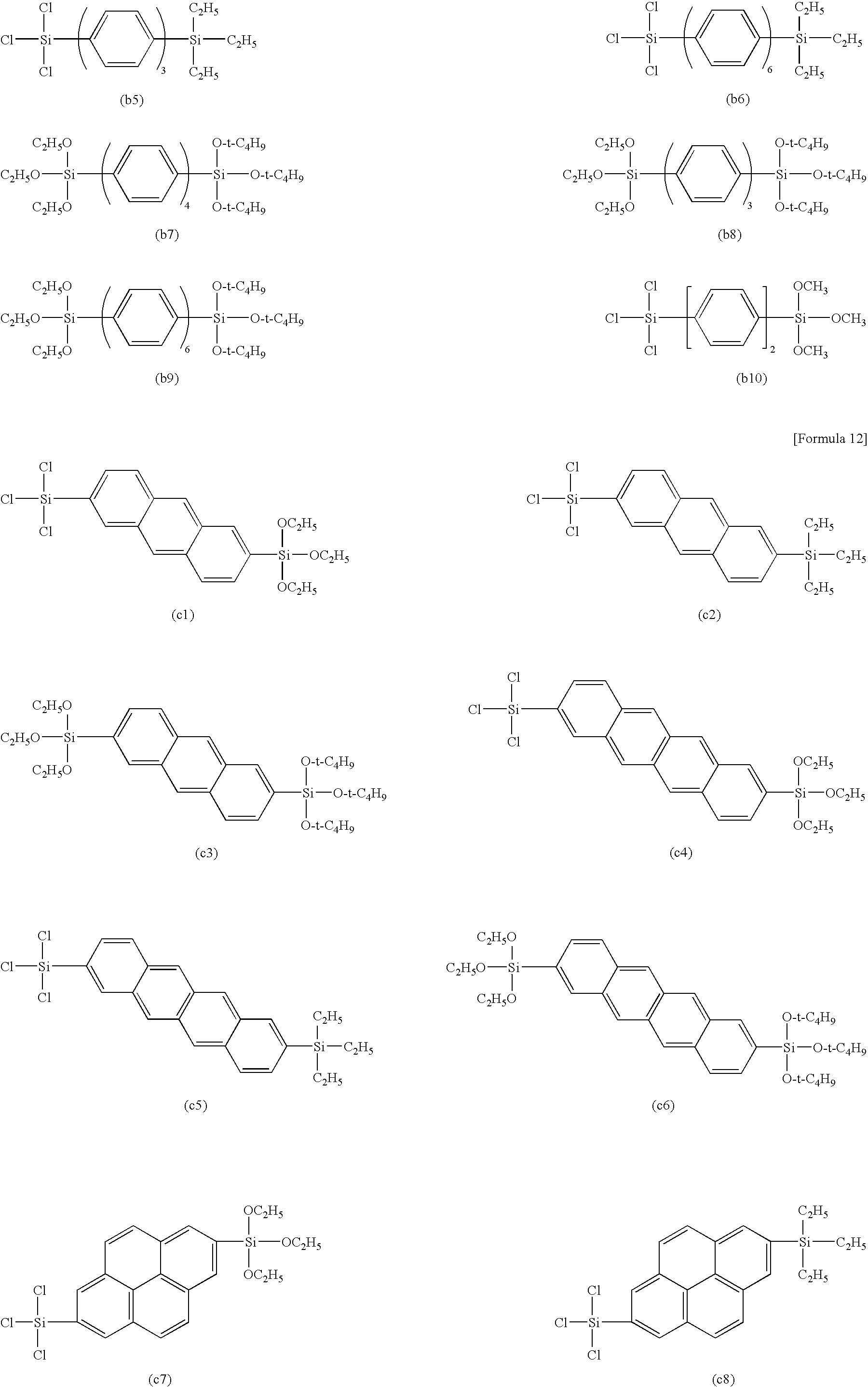

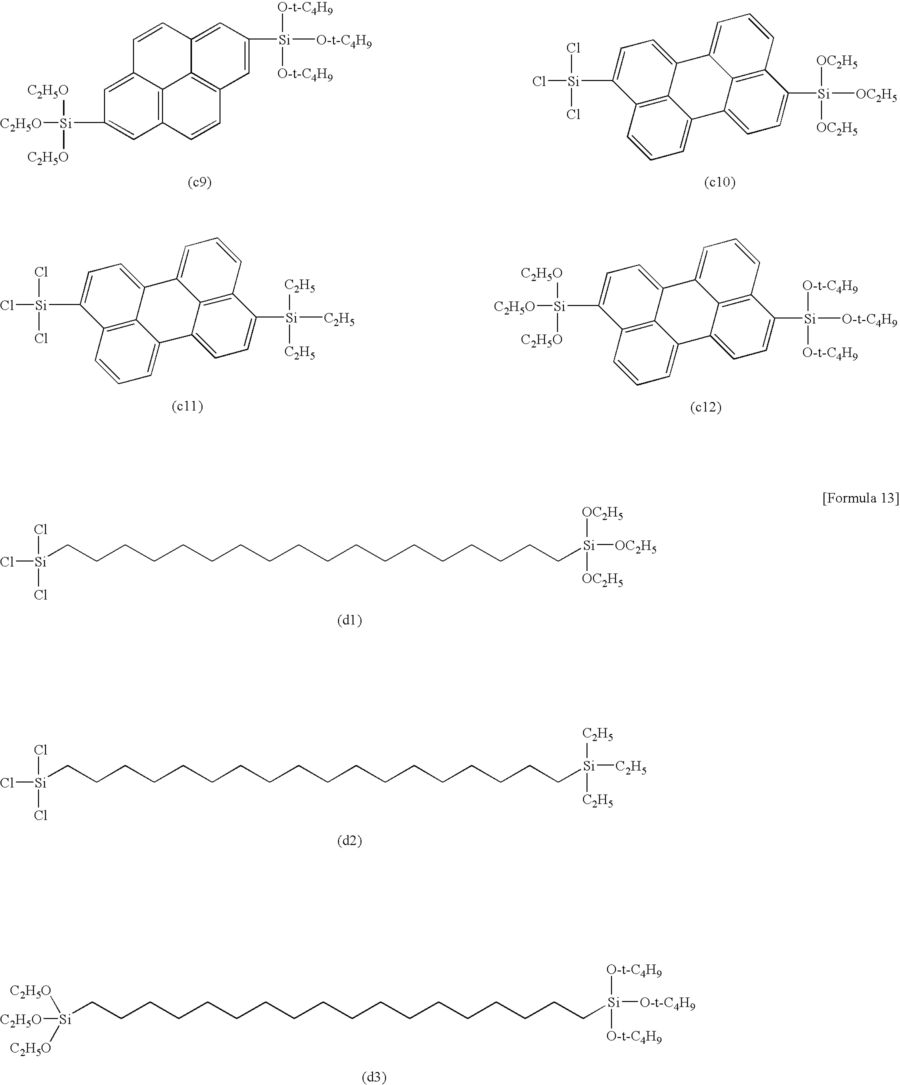

(Preparative Method)

The organic compounds represented by General Formula (I) (hereinafter, referred to as organic compound (I)) can be prepared by introducing a silyl group onto molecules having a π-electron-conjugated or non-π-electron-conjugated skeleton (hereinafter, the molecules will be referred to together as “organic group B-containing molecules”). The sites of the silyl group introduced are not particularly limited, if the single monomolecular film or the multilayer unimolecular film obtained has such a molecular crystallinity that the molecules therein are placed orderly, but are normally both terminals of the molecule. In particular, when the organic group B-containing molecule has a linear shape, the silyl group is introduced to both terminals of the molecule. Alternatively when the organic group B-containing molecule has a point symmetry in shape, the silyl group is preferably introduced in such a way that the central point of the site of the silyl group introduced in general structural formula becomes the center of the molecule.

Silylation of the organic group B-containing molecule can be performed in various known methods. Examples thereof include: (1) reaction of a Grignard reagent or a lithium reagent obtained from a corresponding compound having a halogen atom such as bromine, chlorine, or iodine with an organic silicon compound having a halogen atom or an alkoxy group; (2) hydrosilation reaction of heating and stirring a corresponding compound having a carbon-carbon multiple bond and an organic silicon compound having at least one hydrogen on the silicon atom in the presence of a catalyst such as chloroplatinic acid; and (3) reaction of preparing a substituted olefin in cross-coupling of a corresponding vinyl boron compound with an organic halogenated silicon compound in the presence of a palladium catalyst.

More specifically, favorable methods include the followings:

For example in the first method, a compound represented by (Formula):
H—B—MgX (2)
(wherein, B is the same as B in General Formula (I) above, and X represents a halogen atom) and a compound represented by (Formula):
Y¹—Si(A¹)(A²)(A³) (3)
(wherein, Y¹ represents a halogen atom, and A¹ to A³ are the same as those in General Formula (I) above) (for example, tetrachlorosilane or tetraethoxysilane) are allowed to react with each other, forming a compound represented by (Formula):
H—B—Si(A¹)(A²)(A³) (4);
then, a halogen atom is bound to B in Formula (4); the product is then allowed to react with magnesium or lithium metal in the presence of ethoxyethane or tetrahydrofuran (THF), forming a compound represented by (Formula):
MgX—B—Si(A¹)(A²)(A³) or Li—B—Si(A¹)(A²)(A³) (5);
which in turn is allowed to react with a compound represented by (Formula):
Y²—Si(A⁴)(A⁵)(A⁶) (6)
(wherein, Y² represents a halogen atom, and A⁴ to A⁶ are the same as those in General Formula (I) above) (for example, tetraethoxysilane, tetrabutoxysilane, or tetramethoxysilane), to give an organic compound (I).

In the second method, a compound represented by (Formula):
X¹—B—X² (8)
(wherein, B is the same as that in General Formula (I); and X¹ and X² each differently a halogen atom) is converted to a Grignard reagent by using a metal catalyst of magnesium or lithium, and the product is allowed to react with a compound represented by (Formula):
Y¹—Si(A¹)(A²)(A³) (3)
(wherein, Y¹ represents a halogen atom; A¹ to A³ are the same as those in General Formula (I) above), to give a Grignard reagent represented by the following formula:
Si(A¹)(A²)(A³)-B—MgX² (9);
and then, a compound represented by (Formula):
Y²—Si(A⁴)(A⁵)(A⁶) (6)
(wherein, Y² represents a halogen atom, and A⁴ to A⁶ are the same as those in General Formula (I) above) is allowed to react with the compound represented by (Formula 9), to give the organic compound (I). In the first and second methods, the halogen atom is a chlorine, bromine, iodine, or other atom.

The reaction temperature during preparation above is preferably, for example, −100 to 150° C., more preferably −20 to 100° C. The reaction period is, for example, about 0.1 to 48 hours in each step. The reaction is carried out normally in an organic solvent inert to the reaction. Examples of the organic solvents having no adverse effect on the reaction include aliphatic or aromatic hydrocarbons such as hexane, pentane, benzene, and toluene; ether solvents such as diethylether, dipropylether, dioxane, and tetrahydrofuran (THF); chlorine-based hydrocarbons such as methylene chloride, chloroform, and carbon tetrachloride; and the like, and these solvents may be used alone or in combination of two or more. Among the solvents above, diethylether and THF are favorable. A catalyst may be added freely in the reaction. Any one of known catalysts such as platinum catalyst, palladium catalyst, and nickel catalysts may be used.

Preferably in the first and second methods, Y¹ is higher in elimination reactivity than A¹ to A³, and Y² higher in elimination reactivity than A⁴ to A⁶. In particular, Y¹ and Y² are preferably iodine atoms.

Alternatively, a silyl group may also be introduced by the following method.

For example, a Grignard reagent having the π-electron- or non-π-electron-conjugated skeleton is first prepared. The Grignard reagent obtained is allowed to react with a silane compound having a silyl group containing groups relatively lower in elimination reactivity (A⁴ to A⁶) such as tetraethoxysilane, tetrabutoxysilane, or tetramethoxysilane in an organic solvent at −200 to −60° C. for 10 to 30 hours, to introduce a silyl group onto one terminal of an organic group B-containing molecule. Then, the compound obtained is allowed to react with a silane compound having a silyl group with groups relatively higher in elimination reactivity (A¹ to A³) such as tetrachlorosilane or tetraethoxysilane in an organic solvent at −200 to −60° C. for 10 to 30 hours, to introduce a silyl group onto the other terminal of the organic group B-containing molecule. Independently of the silyl group introduced, the organic solvent is not particularly limited, if it does not inhibit the silylation reaction, and examples thereof include aliphatic hydrocarbons such as hexane and pentane; ethers such as diethylether, dipropylether, dioxane, and tetrahydrofuran (THF); aromatic hydrocarbons such as benzene, toluene, and nitrobenzene; chlorine-based hydrocarbons such as methylene chloride, chloroform, and carbon tetrachloride; and the like. These solvents may be used alone or as a liquid mixture.

A silyl group may be introduced onto the organic group B-containing molecule without preparation of a Grignard reagent. For example, an organic group B-containing molecule is allowed to react with a silane compound having a silyl group containing groups relatively lower in elimination reactivity (A⁴ to A⁶) such as tetraethoxysilane, tetrabutoxysilane, or tetramethoxysilane in an organic solvent at −200 to −60° C. for 10 to 30 hours, to introduce the silyl group onto one terminal of the organic group B-containing molecule. Then, the compound obtained is allowed to react with a silane compound having a silyl group with groups relatively higher in elimination reactivity (A¹ to A³) such as tetrachlorosilane or tetraethoxysilane in an organic solvent at −200 to −60° C. for 10 to 30 hours, to introduce a silyl group onto the other terminal of the organic group B-containing molecule. The organic solvent used is the same as that described above.

The organic compound according to the present invention thus prepared by such a method may be isolated and purified from the reaction solution by any one of known means such as re-solubilization, concentration, solvent extraction, fractionation, crystallization, recrystallization, chromatography, and the like.

Hereinafter, examples of the methods of preparing a compound having two or more monocyclic aromatic compounds and/or monocyclic heterocyclic compounds bound to each other or a compound having an acene skeleton, a favorable precursor of the organic group B, will be described.

(1) Compound having two or more monocyclic aromatic compounds and/or monocyclic heterocyclic compounds bound to each other

Examples of the methods of preparing a compound containing only benzene or thiophene are shown below in (A) to (C). In the following preparative examples of the compound having only thiophene rings, only a reaction from thiophene trimer to hexamer or heptamer is shown. However, it is possible to form a compound other than the hexamer or heptamer, in reaction with a thiophene compound different in unit number. For example, it is possible to form a thiophene tetramer or pentamer by coupling 2-chlorothiophene molecules and allowing 2-chlorobithiophene chlorinated by NCS to react in a similar manner to that described below. It is also possible to form thiophene octamer or nonamer by chlorination of the thiophene tetramer with NCS.

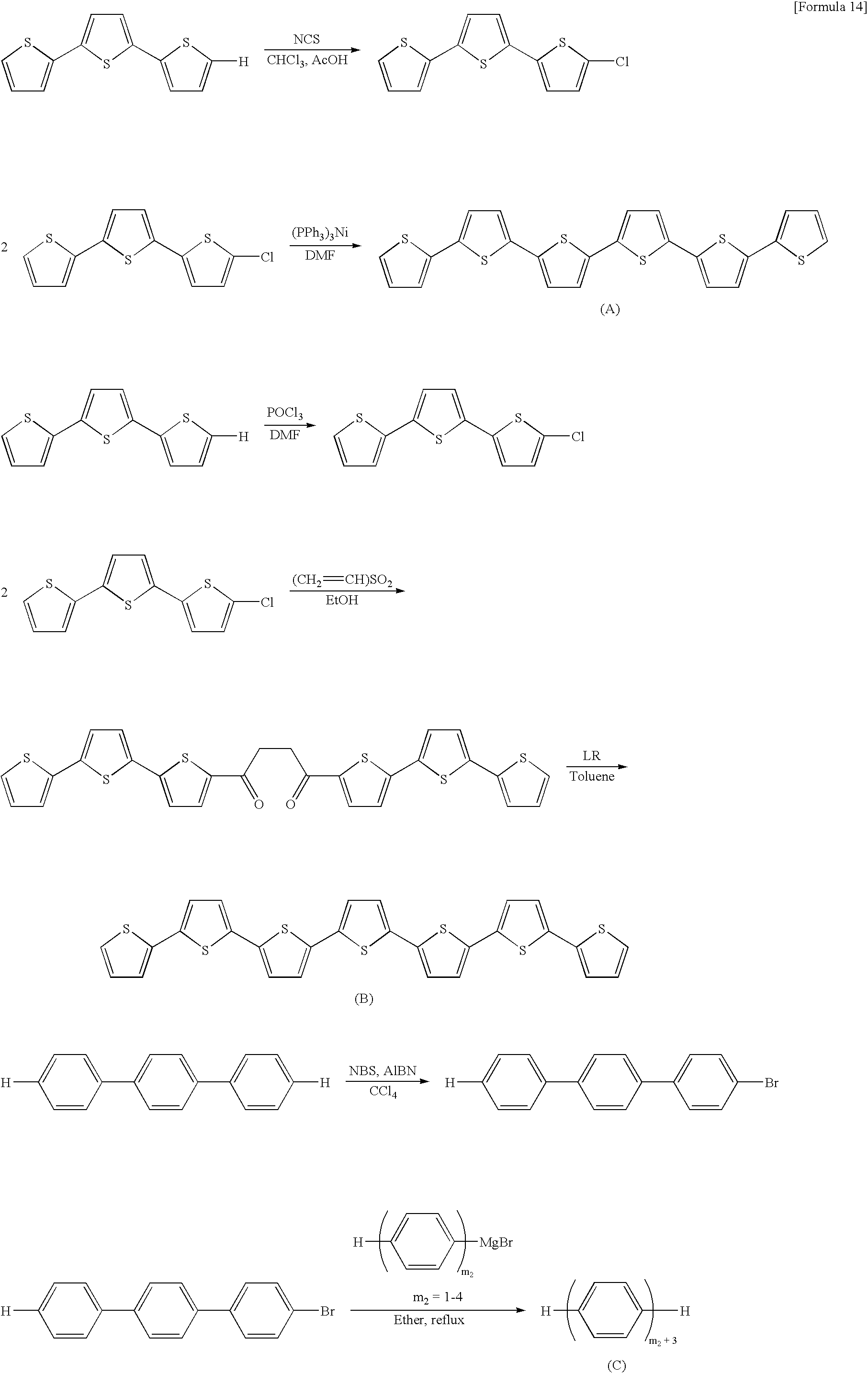

For example, Grignard reaction may be used for preparation of a block compound by direct binding of a block having a certain number of thiophene-derived units bound to each other to a block having a certain number of benzene-derived units bound to each other. In such a case, the following method may be used for preparation.

A simple benzene or thiophene compound is first haloganated (for example, brominated) at predetermined positions, and then debrominated and borated by addition of n-BuLi and B(O-iPr)₃. The solvent then is preferably ether. The boration reaction is carried out in two phases, and the reaction in the first phase is preferably carried out at −70° C. for stabilization of the reaction in the early period and the reaction in the second phase at a temperature gradually increasing from −70° C. to room temperature. Separately, an intermediate for the block compound is prepared in Grignard reaction from benzenes or thiophenes having halogen groups (for example, bromo groups) at both terminals.

It is possible to initiate coupling of the unreacted bromo group with the borated compound by dissolving them, for example, in toluene solvent in the state, allowing them to react with each other in the presence of Pd(PPh₃)₄ and Na₂CO₃ at a reaction temperature of 85° C. until completion of the reaction, and consequently, to prepare the block compound.
Examples of the synthetic routes for compounds (D) and (E) in such a reaction are shown below.

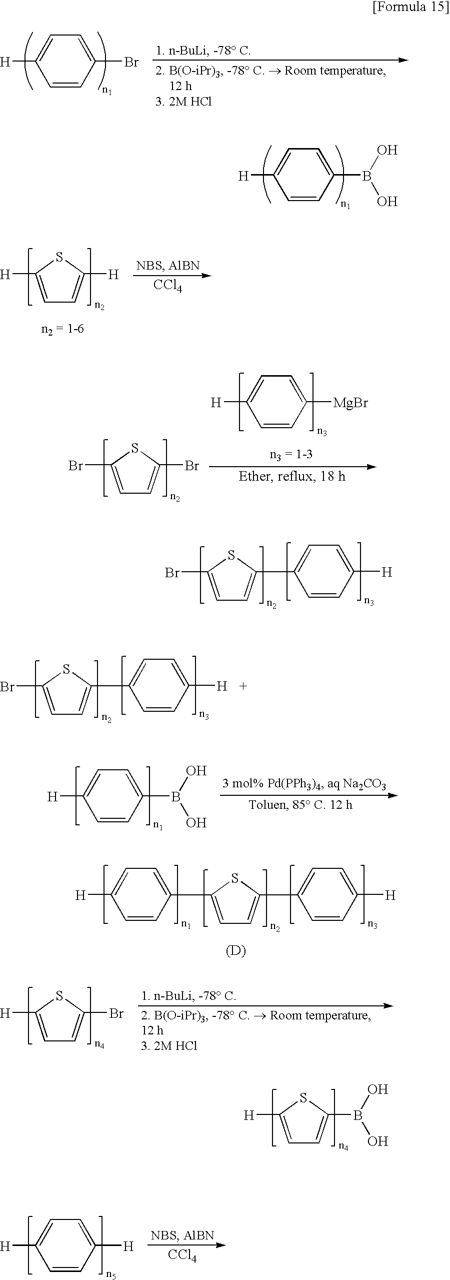

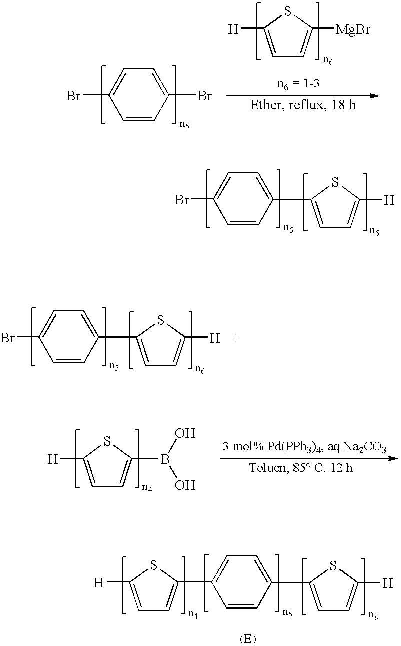

For example, the following method is applicable as the method of preparing the compound having benzene- or thiophene-derived units and vinyl groups (unsaturated aliphatic compounds) that are bound to each other alternately. Specifically, a raw material having methyl groups at the reaction sites of benzene or thiophene is made available, and the both terminals thereof are brominated by using 2,2′-azobisisobutylonitrile (AIBN) and N-bromosuccinimide (N-bromosuccinimide: NBS). Then, the brominate product is allowed to react with PO(OEt)₃, forming an intermediate. Then, a compound having an aldehyde group at the terminal and the intermediate are allowed to react, for example, in DMF solvent in the presence of NaH, to give the compound described above. The compound obtained has a methyl group at the terminal, and thus, it is possible to prepare a compound containing more units, for example, by brominating the methyl group additionally and applying the preparative process once again.

Examples of the methods of preparing compounds (F) to (H) different in length in such a reaction are shown below.

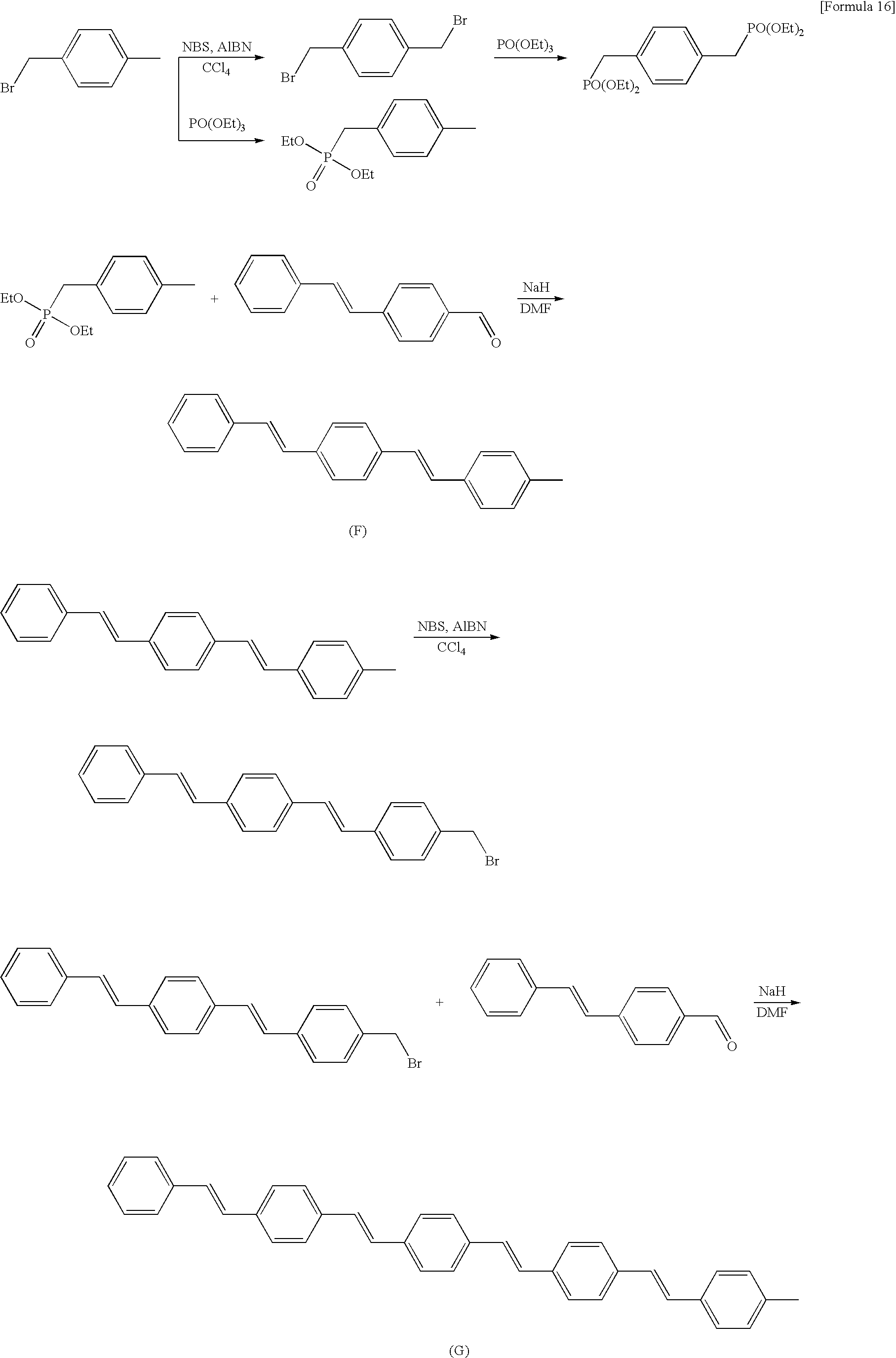

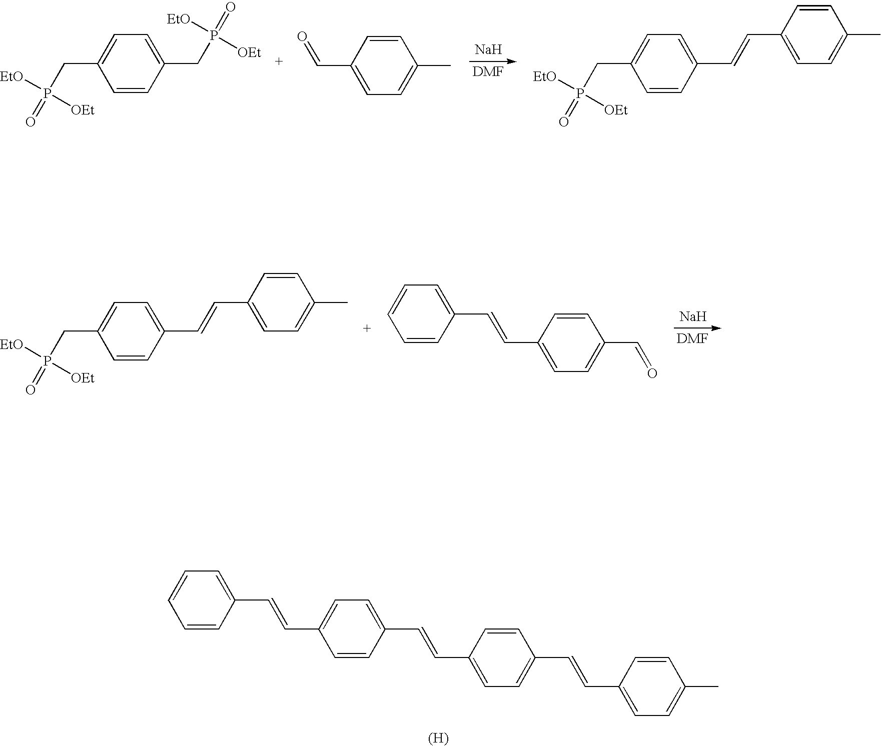

It is possible to use a raw material having a side chain (e.g., alkyl group) at a particular position for any compound. Thus, for example, it is possible to obtain 2-octadecyl sexithiophene as compound (A) in the synthetic route by using 2-octadecyl terthiophene as the raw material. Similarly, by using a raw material having a side-chain previously connected to a particular position it is possible to obtain any compound (A) to (H) above having a side chain.

The raw materials used in the preparative examples above are commonly-used reagents and commercially available from reagent makers. The CAS numbers and the purities of the raw materials used, when obtained for example from a reagent maker KISHIDA CHEMICAL Co., Ltd, are shown below.

TABLE 1

| Raw material | CAS No. | Purity |
|---|---|---|
| 2-Chlorothiophene | 96-43-5 | 98% |
| 2,2′,5′,2″-Terthiophen | 1081-34-1 | 99% |
| Bromobenzene | 108-86-1 | 98% |
| 1,4-Dibromobenzene | 106-37-6 | 97% |
| 4-Bromobiphenyl | 92-66-0 | 99% |
| 4,4′-Dibromobiphenyl | 92-86-4 | 99% |
| p-Terphenyl | 92-94-4 | 99% |
| α-Bromo-p-xylene | 104-81-4 | 98% |

(2) Compound having an Acene Skeleton

Examples of the methods of preparing a compound having an acene skeleton include (1) a method of repeating the steps of substituting the hydrogen atoms bound to two carbon atoms at the predetermined positions of a raw material compound with ethynyl groups and ring-closing the ethynyl groups, (2) a method of repeating the steps of substituting a hydrogen atom bound to the carbon atom at the predetermined position of a raw material compound with a triflate group, allowing it to react with furan or the derivative thereof, and oxidizing the product, and the like. Examples of the method of preparing an acene skeleton by such a method will be described below.

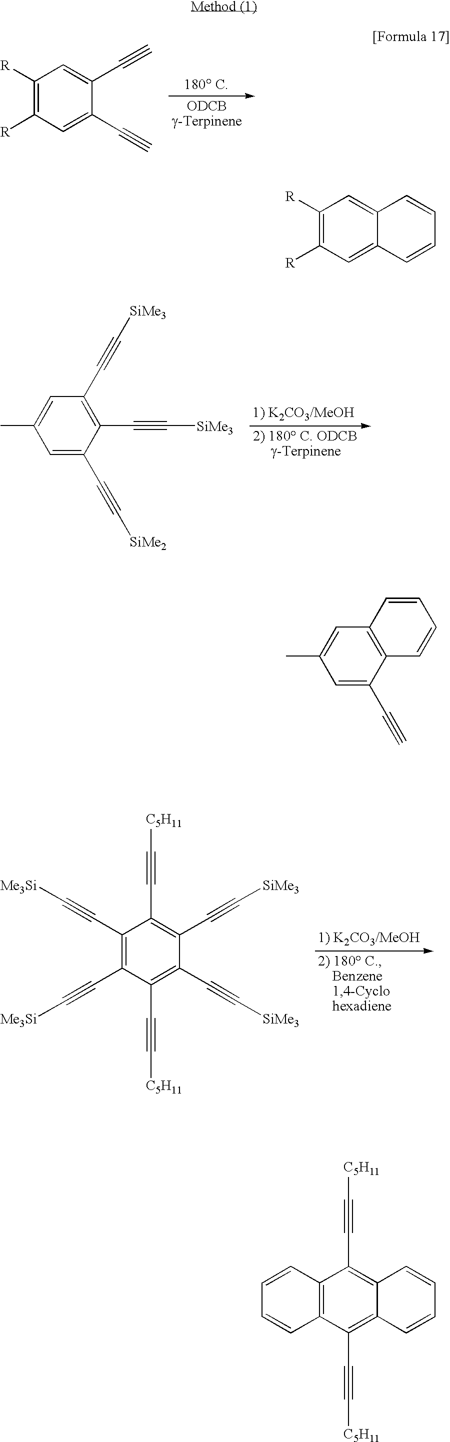

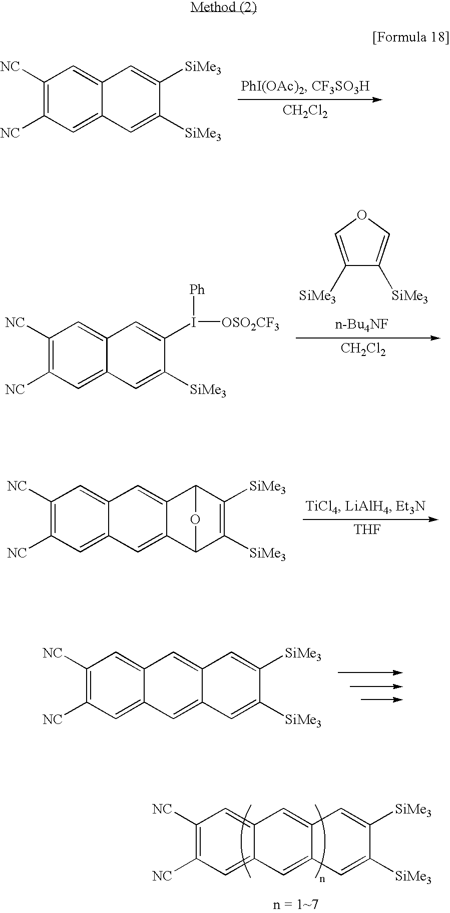

In method (2), wherein the benzene rings in the acene skeleton are added one by one, it is possible to prepare a compound having an acene skeleton similarly, for example, even when the raw material compound has a functional or protecting group lower in reactivity at a particular site. An example in such a case is shown below.

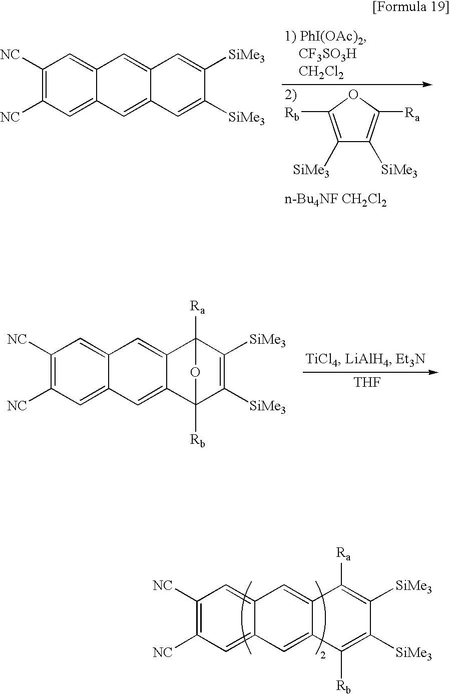

In the Formula above, Ra or Rb is preferably a functional or protecting group lower in reactivity such as a hydrocarbon group or a ether group.

In the reaction formula of method (2), the starting compound having two acetonitrile groups and two trimethylsilyl groups may be replaced with a compound having trimethylsilyl groups as these groups. It is also possible to obtain a compound substituted with two hydroxyl groups and having one more benzene rings than the starting compound, by heating the reaction product, after the reaction with the furan derivative in the reaction formula above, under reflux in the presence of lithium iodide and DBU (1,8-diazabicyclo[5.4.0]undec-7-ene).

The raw materials used in the preparative examples above are commonly-used reagents and commercially available from reagent makers. For example, tetracene is available from Tokyo Chemical Industry CO., LTD at a purity of 97% or more.

(Organic Thin Film and Method of Preparing the Same)

The organic thin film formed with the organic compound (I) may have a single monomolecular film structure or a multilayer unimolecular film structure, and, when it is a multilayer unimolecular film, at least one, preferably at least two, monomolecular film constituting the multilayer film is preferably formed with the organic compound (I).

Hereinafter, favorable embodiments of the organic thin film will be described.

When the organic thin film has a single monomolecular film structure having only one monomolecular film on the substrate, the monomolecular film is formed by using the organic compound (I), and, when it is a multilayer unimolecular film structure having first to n'th monomolecular films on the substrate (n is an integer of 2 or more), at least the first to (n−1)'th monomolecular films, more preferably all monomolecular films, are formed by using the organic compound (I). When the organic thin film has a multilayer unimolecular film structure, each of the monomolecular films is numbered from the side close to the substrate.

When the organic thin film has a multilayer unimolecular film structure, the organic compound for the n'th monomolecular film (outmost layer film) is not particularly limited, if it has a reactive group forming a chemical bond in reaction with a silyl group having A⁴ to A⁶ of the organic compound (I) forming the (n−1)'th monomolecular film, and examples thereof include organic compounds having a reactive group such as silyl group having A¹ to A³, halogen atom, hydroxyl group, carboxyl group, or the like. The organic compound (I) described above is favorably used.

When the organic thin film has a multilayer unimolecular film structure, the organic compounds (I) forming the first to (n−1)'th monomolecular films, as needed the first to n'th monomolecular films, may be selected independently in the range above in each film. For example, the organic compounds (I) used in part or all of the films may be the same as or different from each other.

The substrate is selected properly according to applications of the organic thin film. Examples thereof include semiconductors, for example, element semiconductors such as silicon and germanium, and compound semiconductors such as GaAs, InGaAs, and ZnSe; glass and quartz glass; insulative polymer films such as of polyimide, polyethylene, polyethylene terephthalate (PET), polytetrafluoroethylene, PEN, PES, and Teflon (registered trade name); stainless steel (SUS); metals such as gold, platinum, silver, copper, and aluminum; high-melting point metals such as titanium, tantalum, and tungsten; silicide and polycide with the high-melting point metals; insulators such as silicon oxide (thermally oxidized silicon, low-temperature oxidized silicon: LTO, high-temperature oxidized silicon: HTO), silicon nitride, SOG, PSG, BSG, and BPSG; PZT, PLZT, and ferroelectic or antiferroelectic substances; SiOF—, SiOC— and CF-based materials; and low-dielectric substrates formed by coating such as HSQ (hydrogen silsesquioxane)-based materials (inorganic), MSQ (methyl silsesquioxane)-based materials, PAE (polyarylene ether)-based materials, BCB-based materials or the porous materials thereof, and CF-based materials or the porous materials thereof. In addition, so-called SOI substrates, multilayer SOI substrates, SOS substrates, and the like may also be used. These substrates may be used alone or as they are laminated. For example, the substrate may be made of an inorganic material, which is normally used as an electrode for semiconductor device, and may have a film of organic material formed on the surface. In the present invention, the substrate surface preferably has a hydrophilic group such as hydroxyl or carboxyl, particularly hydroxyl, and, if not, the substrate surface is preferably provided with a hydrophilic group by hydrophilizing treatment. The substrate can be hydrophilized, for example, by immersion in a mixed solution of hydrogen peroxide and sulfuric acid, irradiation of UV light, or the like.

When the organic thin film has either a single monomolecular film or multilayer unimolecular film structure, the organic compound molecules are so placed in the monomolecular film formed by using the organic compound (I) that the silyl groups having A¹ to A³ (hereinafter, referred to as high-reactivity silyl groups) are oriented on the substrate side and the silyl groups having A⁴ to A⁶ (hereinafter, referred to as low-reactivity silyl groups) on the film-surface side.

Thus, for example, when it has the single monomolecular film structure, chemical bonds (in particular, silanol bonds) are formed at the interface between the single monomolecular film and the substrate in reaction of the high-reactivity silyl groups and the hydrophilic groups on the substrate surface, and the low-reactivity silyl groups remain on the film-surface side. As a result, the monomolecular film is bound to (or adsorbed on) the substrate by the high-reactivity silyl groups.

For example, when it has the multilayer unimolecular film structure having first and second monomolecular films formed in that order on a substrate, chemical bonds (in particular, silanol bonds (—Si—O—)) are formed at the interface between the first monomolecular film and the substrate in reaction of the high-reactivity silyl groups in the first monomolecular film and the hydrophilic groups on the substrate surface. Also at the interface of the first and second monomolecular films, chemical bonds (e.g., siloxane bonds (—Si—O—Si—)) are formed in reaction of the low-reactivity silyl groups in the first monomolecular film and the reactive groups in the second monomolecular film (e.g., silyl group). As a result, the first monomolecular film is bound to (adsorbed on) the substrate by the high-reactivity silyl groups and bound to (adsorbed on) the second monomolecular film by the low-reactivity silyl groups.

For example, in the case of a multilayer unimolecular film structure having the first to n'th monomolecular layers (n is an integer of 3 or more) on a substrate in that order, chemical bonds (in particular, silanol bonds (—Si—O—)) are formed at the interface between the first monomolecular film and the substrate in reaction of the high-reactivity silyl groups in the first monomolecular film and the hydrophilic groups on the substrate surface. In addition, chemical bonds (in particular, siloxane bonds) are formed at the interface between the k'th monomolecular film (k is an integer of 2 or more and (n−1) or less) and the (k−1)'th monomolecular film in reaction of the high-reactivity silyl groups in the k'th monomolecular film and the low-reactivity silyl groups in the (k−1)'th monomolecular film. When k is an integer of 2 or more and (n−2) or less, chemical bonds (in particular, siloxane bonds) are formed at the interface between the k'th monomolecular film and the (k+1)'th monomolecular film in reaction of the low-reactivity silyl groups in the k'th monomolecular film and the high-reactivity silyl groups in the (k+1)'th monomolecular film. Alternatively when k is (n−1), chemical bonds (e.g., siloxane bonds) are formed at the interface between the k'th monomolecular film and the (k+1)'th monomolecular film (outmost layer film) in reaction of the low-reactivity silyl groups in the k'th monomolecular film and the reactive groups in the (k+1)'th monomolecular film (e.g., silyl groups). As a result, the k'th monomolecular film is bound to the (k−1)'th monomolecular film by the high-reactivity silyl groups and to the (k+1)'th monomolecular film by the low-reactivity silyl groups. Thus, the second to (n−1)'th monomolecular films are respectively bound to (or adsorbed on) the monomolecular films immediately below by the high-reactivity silyl groups and to the monomolecular films immediately above by the low-reactivity silyl groups.

In particular when the organic thin film has a multilayer unimolecular film structure and all monomolecular films are formed with the organic compound (I), the monomolecular film of the bottom layer is bound to the substrate via chemical bonds, in particular via silanol bonds, and the other monomolecular films are respectively bound to the monomolecular films immediately below via chemical bonds, in particular via siloxane bonds.

The alignment of the organic compound (I) molecules in the monomolecular film formed by using the organic compound (I) is performed, by controlling the elimination reactivity of the two silyl groups at both terminals of the organic compound (I). As a result, it is possible to produce a single monomolecular film and the multilayer film thereof uniform in film thickness and having molecular crystallinity in which the molecules are aligned orderly, at high reproducibility. Thus, the functional groups bound to the silyl group should be liberated and substituted with a hydroxyl group or proton, for making the silylated organic compound bound via a silanol or siloxane bond. In the present invention, the compound molecules are allowed to react with the hydroxyl groups (or carboxyl groups) on the surface of the substrate or the monomolecular film immediately below by using the difference in elimination reactivity between two silyl groups and substituting selectively the groups (A¹ to A³) relatively higher in elimination reactivity in one silyl group with a hydroxyl group or proton. As a result, silanol or siloxane bonds are formed by orientation of the silyl groups containing A¹ to A³ groups on the substrate side. The other silyl group has only groups relatively lower in elimination reactive (A⁴ to A⁶), and such groups are resistant to substitution with a hydroxyl group or proton and thus, remain unreactive with the substrate or the monomolecular film immediately below and orient themselves on the film surface side. The A⁴ to A⁶ group-containing silyl group is activated during formation of the monomolecular film immediately above, as it is used as a reaction site. As a result, the compound molecules are aligned in the same direction in each monomolecular film, giving a single monomolecular film or the multilayer film thereof, uniform in thickness and having molecular crystallinity. If the silyl groups at both terminals have groups relatively higher in elimination reactivity, the compound molecules dimerize or trimerize partially in the thickness direction in each monomolecular film, giving a thin film uneven in thickness and prohibiting desired molecular crystallinity.

When the organic thin film is a single monomolecular film, the film thickness may be adjusted properly according to the kind of the organic group B, but is, for example, approximately 1 to 12 nm, preferably, approximately 1 to 3.5 nm, considering its cost and mass productivity. In the case of a multilayer unimolecular film, the film thickness is about c×d, when the thickness of the monomolecular film is designated as c and the number of the layers d. In preparation of a thin film having monomolecular films different in function, which demands modification of the molecular structure and film thickness of each monomolecular film according to the desirable function, the thickness of the multilayer unimolecular film may be altered suitably as needed.

In such a single monomolecular or multilayer unimolecular film, the organic compound (I) is easily self-structured, and gives a thin film in which the units (molecules) are aligned in a certain direction. Thus, it is possible to minimize the distance between neighboring units and give a highly crystallized organic thin film, and consequently, to give an organic thin film showing conductivity in the direction perpendicular to the substrate surface.

Si atoms in neighboring organic compound (I) molecules are crosslinked directly or indirectly via an oxygen atom, lowering the distance between neighboring units and improving crystallization further, for example, in the Si—O—Si network. In particular when the units are aligned linearly, the neighboring units do not bind to each other, and yet, minimize the distance between neighboring units, and give a highly crystallized material. Such alignment of the units gives an organic thin film showing semiconductor characteristics in the surface direction of the substrate.

Thus, it is possible to give a thin film having electrical anisotropy in which the electrical properties vary in the directions perpendicular to and parallel with the substrate surface.

The method of forming an organic thin film by using the organic compound (I) will be described below briefly with reference to drawings.

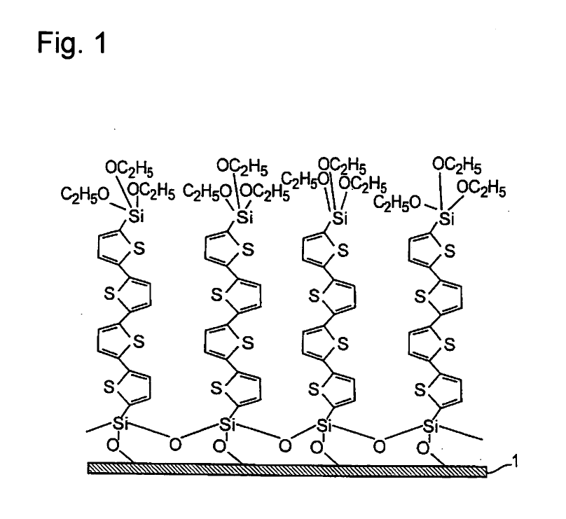

In formation of the organic thin film, a monomolecular film is first formed, in reaction of the silyl group having A¹ to A³ in the organic compound (I) used with a substrate surface, by a method such as LB method, immersion method, or coating method. Because the organic compound (I) has two silyl groups different in elimination reactivity of groups (A¹ to A³ and A⁴ to A⁶) at both terminals, the silyl group having groups relatively higher in elimination reactivity (A¹ to A³) is bound selectively to the substrate surface. As shown in FIG. 1, which is a schematic diagram showing the monomolecular film formed by using the compound represented by Formula (a1) above, chlorine atoms relatively higher in elimination reactivity are substituted to hydroxyl groups and the hydroxyl group-containing silyl groups are bound selectively to the substrate surface. In FIG. 1, the functional groups in the terminal silyl group on the film surface (air interface) side are more resistant to elimination, prohibiting adsorption reaction with other molecules or on the substrate.

In the present invention, the groups higher in elimination reactivity are substituted selectively with a hydroxyl group or proton, to make the silyl group having the groups relatively higher in elimination reactivity (A¹ to A³) bind selectively to the substrate. It is preferable for that purpose to modify the solvent atmosphere, reaction temperature, and the like during film formation, by using the difference in reactivity of respective groups (A¹ to A⁶) under the reaction condition. For example, it is possible to adjust the proton concentration of the solvent and to control the reactivity, by changing pH of water when the solvent is water, and by using a hydroxylated solvent when the solvent is an organic solvent.

For example, when a monomolecular film is formed by using an organic compound having halogen atoms as A¹ to A³ and alkoxy groups as A⁴ to A⁶ by the LB method described below, it is possible to substitute only the A¹ to A³ groups with hydroxyl groups by adjusting the pH of water to 7. When a monomolecular film is formed by using the organic compound by the immersion method described below, it is not always necessary to adjust the pH or others, because A¹ to A³ are easily substituted with hydroxyl groups by the water present in trace amount in the organic solvent containing the dissolved organic compound.

For example, when a monomolecular film is formed by using an organic compound having ethoxy groups as A¹ to A³ and butoxy groups as A⁴ to A⁶ by the LB method described below, it is possible to substitute only A¹ to A³ with hydroxyl groups by adjusting the pH of water to 4.

In the LB method (Langmuir Blodget method), a thin film is formed on the water surface by dissolving an organic compound (I) in an organic solvent and adding the obtained solution dropwise onto the water surface previously pH-adjusted. The groups relatively higher in elimination reactivity (A¹ to A³) in the silyl group at one terminal of the organic compound are then converted to hydroxyl groups by hydrolysis. Then, a single monomolecular film shown in FIG. 1 is obtained, by allowing the silyl group having the groups relatively higher in elimination reactivity (A¹ to A³) in the organic compound to bind to the substrate while the substrate having hydrophilic groups (in particular, hydroxyl groups) on the surface is pulled up from the water surface under pressure.

Alternatively in the immersion or coating method, an organic compound (I) is dissolved in an organic solvent. For example, an organic compound (I) is dissolved in a non-aqueous organic solvent such as hexane, chloroform, or carbon tetrachloride to obtain a solution having a concentration of approximately 1 to 100 mM. A substrate having hydrophilic groups (in particular, hydroxyl groups) on the surface is immersed in and pulled up from the solution obtained. Alternatively, the solution obtained is coated on the surface of the base material. The groups relatively higher in elimination reactivity (A¹ to A³) in the silyl group at one terminal of the organic compound are then hydrolyzed into hydroxyl groups by water present in the organic solvent in a trace amount. The silyl group having the groups relatively higher in elimination reactivity (A¹ to A³) in the organic compound is then bound to the substrate by storing the substrate as it is for a particular time, to give the monomolecular film shown in FIG. 1.

After formation of the single monomolecular film, unreacted organic compounds are normally removed from the monomolecular film by using a non-aqueous solvent. After cleaning, the substrate is washed with water and dried at room temperature or under heat, allowing fixation of the organic thin film. The thin film may be used as it is as an organic thin film, or may be treated additionally, for example, by electrolytic polymerization.

In forming a multilayer unimolecular film, a monomolecular film of organic compound (I) is formed additionally by using the unreacted silyl groups present on the film-surface side of the previously formed single monomolecular film as the sites for adsorption reaction. Among many organic compounds (I), the organic compound used may be the same as or different from that for the previously formed monomolecular film, or may be the “organic compound used for the n'th monomolecular film (outmost layer film)”. Before forming a monomolecular film additionally, groups A⁴ to A⁶ (ethoxy groups in FIG. 1) in unreacted silyl groups present on the film surface side of the previously formed monomolecular film are normally converted into hydroxyl group by activation, for example by adjusting the solvent atmosphere and reaction temperature as described above. For example, the surface of the previously formed monomolecular film is brought into contact with water previously adjusted to a particular pH. Specifically, the previously formed monomolecular film is immersed in water at a particular pH, or alternatively, water at a particular pH is coated dropwise on the monomolecular film surface. In this way, the monomolecular film is additionally formed more effectively, by using the unreacted silyl groups as the sites for adsorption reaction.

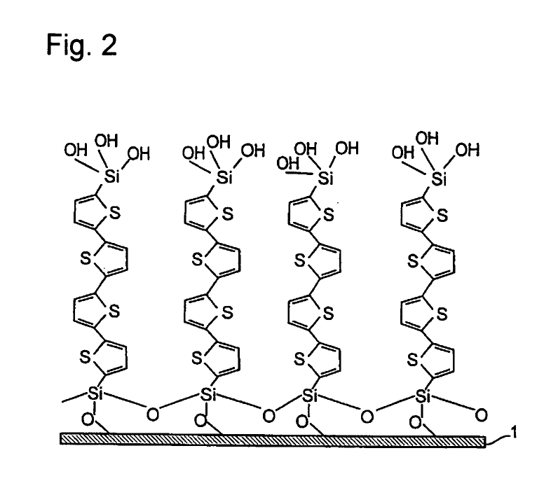

The additional monomolecular film is formed by a method similar to that described above, for example, by the LB method, immersion method, or coating method. In particular when the LB method is used, the A⁴ to A⁶ groups (ethoxy groups in FIG. 1) on the previously formed monomolecular film surface can be converted into hydroxyl groups by adjusting the water used to a particular pH. If the A⁴ to A⁶ groups before substitution are reactive with the organic compound in the newly formed monomolecular film at some level, they may be left as they are without substitution with hydroxyl groups. FIG. 2 is a schematic diagram showing the monomolecular layer when the ethoxy groups in the unreacted silyl group present on the film surface side in FIG. 1 are substituted with hydroxyl groups.

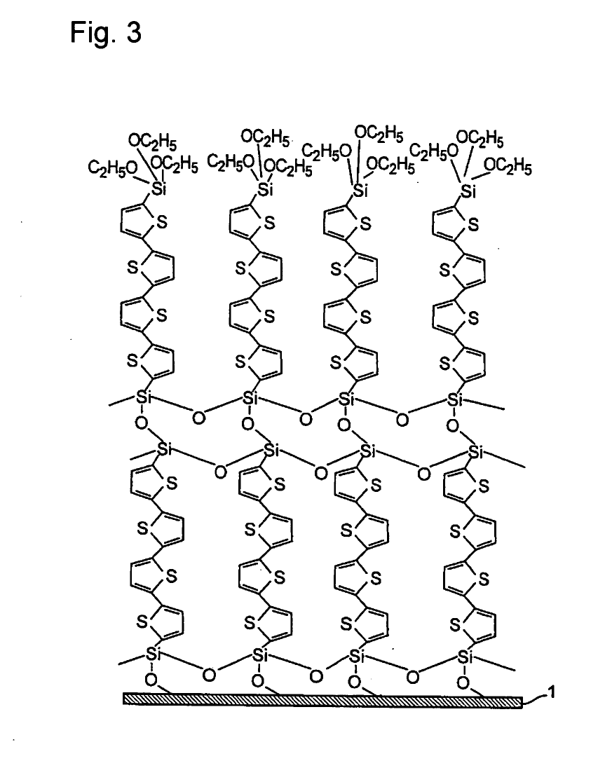

FIG. 3 shows an example of a bilayer film having two monomolecular films. Although a monomolecular film of the organic compound same as that for the monomolecular film shown in FIG. 2 is formed thereon in FIG. 3, the monomolecular film formed additionally may be formed with an organic compound different from that for the film immediately below.

When the monomolecular film formed additionally is formed with the organic compound (I), it is possible to form monomolecular films, the same or different in organic compound (I), on a substrate one by one and uniformly by repeating the process described above. In any monomolecular film, the silyl group having the groups relatively higher in elimination reactivity (A¹ to A³) of the organic compound (I) binds chemically, selectively to the surface of the substrate or the monomolecular film immediately below, and thus, the thin film obtained is uniform in film thickness and superior in molecular crystallinity. In the present invention, it is possible to obtain the advantageous effects of the present invention, even when a multilayer film consisting of 2 to 20, in particular 2 to 10, monomolecular films is formed as they are laminated. The total film thickness then is not specified particularly, because it depends on the length of the compound molecule used, but normally 4 to 300 nm, particularly preferably 4 to 100 nm.

Among all monomolecular films constituting the thin film in the organic thin film above, the monomolecular film of organic compound (I) is a self-structured film in which the molecules therein aggregate by non-covalent bonding, specifically, by van der Waals, electrostatic, or π-π stacking interaction. It is possible to form a highly orientated film easily by using the self-structuring properly of the molecule.

(Applications)

The organic compound (I) according to the present invention is useful in applications demanding uniformity in film thickness and/or high molecular crystallinity (orientation) such as organic device, optical element, and coating agent. It is particularly useful as an organic layer (thin film) component in organic devices such as organic thin-film transistor, organic photoelectric conversion element, and organic electroluminescent element, when the organic group B in the organic compound (I) is a π-electron conjugated group.

By selecting the kind of the organic group B (in particular, presence or absence of heteroatom) and the kind of the functional group (electron accepting or donating group) properly, the organic thin film using the organic compound (I) according to the present invention may be used, for example, as a thin film for conductive materials, photoconductive materials (photoconductor), non-linear optical materials, and the like in organic thin-film transistors such as TFT light-emitting element, solar cell, fuel cell, sensor, and the like. It is also usable as a biosensor, by adding a terminal functional group that can bind, for example, to an enzyme as a ligand. Hereinafter, more typical applications of the organic thin film according to the present invention will be described.
TFT semiconductor layer (region between source and drain)
Films between the electrodes in organic EL elements and organic phosphorescent elements (light-emitting layer, electron-injecting layer, positive hole-injecting layer, etc.)
Films between the electrodes in organic semiconductor lasers (for example, current-injecting laser such as diode) (because the light emitted from the organic thin film by recombination of the holes and electrons injected respectively from electrodes can be withdrawn in a particular direction)
p- and n-type materials in solar cell (because the organic thin film has photoexcitation properties, it is possible to form a solar cell by forming p-n junctions by laminating p- and n-type thin film materials sequentially)
Fuel-cell separator
Films for detection of gaseous molecule in gas sensor or odor in odor sensor, (it is possible, by placing an organic thin film on a comb-shaped electrode, to form a gas sensor measuring the concentration of a gas molecule by the change in conductivity of the organic thin film caused by absorption of the molecule)
Ion-sensitive film of ion sensor
Sensing film of biosensor (for example, immunosensor) (by using enzyme selectivity of organic thin film)

(Organic Device)

The organic device according to the present invention is not particularly limited, if it has an organic thin film formed by using the organic compound (I), and examples thereof include organic semiconductor devices such as organic thin-film transistor, organic photoelectric conversion element, and organic EL element. Such an organic semiconductor device generally demands uniformity in film thickness and high molecular crystallinity, and it is possible to produce a device having a smaller amount of carrier traps between domains with the organic compound according to the present invention.

(Organic Thin-film Transistor)

An organic thin-film transistor has at least a substrate, a gate electrode formed on the substrate, a gate insulation film formed on the gate electrode, source and drain electrodes in contact with or separated from the gate insulation film, and a semiconductor layer.

In the present invention, the transistor may be any one of various configurations such as bottom-contact, top and bottom-contact, and top-contact, depending on the location of the source electrode, drain electrode and semiconductor layer.

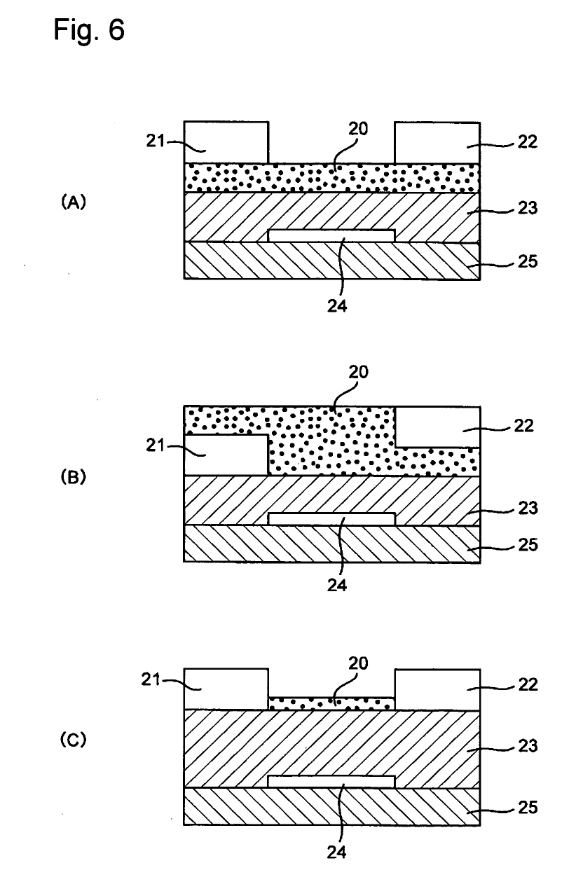

A crosssectional view of a top-contact transistor is shown in FIG. 6(A). The transistor shown in FIG. 6(A) has a configuration comprising a substrate 25, a gate electrode 24 formed on the substrate 25, a gate insulation film 23 formed on the gate electrode 24, a semiconductor layer 20 formed on the gate insulation film 23, and a source electrode 21 and a drain electrode 22 formed as separated on the semiconductor layer 20.

A schematic crosssectional view of a top and bottom-contact transistor is shown in FIG. 6(B). The transistor shown in FIG. 6(B) has a configuration similar to that of the transistor in FIG. 6(A), except that a source electrode 21 is formed on part of the surface of the gate insulation film 23, a semiconductor layer 20 is formed on the source electrode 21 and the other surface of the gate insulation film 23, a drain electrode 22 is formed on part of the surface of the semiconductor layer 20, and the surface of the drain electrode 22 and the other surface of the semiconductor layer 20 form the same plane.

A schematic crosssectional view of a bottom-contact transistor is shown in FIG. 6(C). The transistor shown in FIG. 6(C) has a configuration similar to that of the transistor in FIG. 6(A), except that the source electrode 21 and the drain electrode 22 are formed as separated on the gate insulation film 23, and a semiconductor layer 20 in contact with the source and drain electrodes is formed on the gate insulation film 23 between the source electrode 21 and the drain electrode 22.

In FIGS. 6(A) to (C), the same reference number indicates the same part.

In the present invention, the semiconductor layer 20 is an organic thin film formed by using the organic compound (I), and has a single monomolecular film or multilayer unimolecular film structure. Specifically, the semiconductor layer in FIG. 6(A), (B) or (C) may have a single monomolecular or multilayer unimolecular film structure, and preferably, a multilayer unimolecular film structure.

When the semiconductor layer has a single monomolecular film structure, the monomolecular film is formed by using the organic compound (I). The single monomolecular film is not particularly limited, if it is formed by using the organic compound (I) in the range above, but, in particular, use of the organic compound (I) having a group derived from a monocyclic aromatic compound, a monocyclic heterocyclic compound, a condensed aromatic compound, a condensed heterocyclic compound or a compound having two or more of them to bound each other as the organic group B is preferable; and in particular, use of the organic compound (I) having a group derived from a phenylene compound derivative, a thiophene compound derivative, a perylene derivative, or a pentacene derivative as the organic group B is more preferable. The groups A¹ to A⁶ are not particularly limited, and may be the same as those described above. Such a single monomolecular film is bound to the gate insulation film immediately below via chemical bonds.

When the semiconductor layer has a multilayer unimolecular film structure, the number of the layered monomolecular films is not particularly limited, but, normally 2 to 20, preferably 2 to 10. At least one, preferably all, of the monomolecular film in the semiconductor layers is preferably formed by using the organic compound (I).

For example, the bottom-layer monomolecular film of a bilayer film is preferably formed with an organic compound (I) (each of A¹ to A⁶ is not particularly limited and may be the same as that described above) having, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative; and the second-layer monomolecular film is preferably formed with an organic compound (I) having, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative.

For example, the bottom layer monomolecular film of a trilayer film is preferably formed with an organic compound (I) (each of A¹ to A⁶ is not particularly limited and may be the same as that described above) having, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative; the second-layer monomolecular film is preferably formed with an organic compound (I) (each of A¹ to A⁶ is not particularly limited and may be the same as that described above) having, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative; and the third-layer monomolecular film is preferably formed with an organic compound (I) (each of A¹ to A⁶ is not particularly limited and may be the same as that described above) having, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative.

For example when the semiconductor layer is a multilayer film of 2 to 20 layers, all monomolecular films may be formed with the same organic compound (I). The same organic compound (I) used then for all monomolecular films preferably has, as an organic group B, a group derived from a monocyclic heterocyclic compound, a condensed aromatic compound or a compound having two or more of the compounds above bound to each other, in particular a group derived from a thiophene compound derivative, a perylene derivative, or a pentacene derivative (each of A¹ to A⁶ is not particularly limited and may be the same as that described above).

A dopant may be added to each monomolecular film, independently of whether the semiconductor layer has a single monomolecular film or multilayer unimolecular film structure. The dopant may be any one of those used in the field of organic thin-film transistor, and examples thereof include halogens, iodine, alkali metals, and the like.

The monomolecular film according to the present invention formed as the semiconductor layer of transistor by using an organic compound (I) is bound to the film immediately below via chemical bonds. In particular when all monomolecular films in the multilayer unimolecular film are formed with the organic compound (I), all monomolecular films are bound respectively to the films immediately below via chemical bonds.

The monomolecular film containing no organic compound (I) used as a transistor semiconductor layer may be formed with any organic compound, and, for example, formed with the molecule containing a π-electron-conjugated skeleton, the precursor of the organic group B, exemplified in the description on the organic compound (I).

In preparation of the semiconductor layer, the monomolecular film of organic compound (I) is preferably prepared in a similar manner to the method of forming the organic thin film. The monomolecular film containing no organic compound (I) may be formed, for example, by spin coating, casting, dip coating, or LB method. The thickness of each monomolecular film constituting the semiconductor layer is not specified definitely, because it depends on the molecular length, but preferably 4 to 300 nm, more preferably 4 to 100 nm.

Various known materials traditionally used in the field of organic transistor are applicable to the substrate 25, gate electrode 24, gate insulation film 23, source electrode 21 and drain electrode 22.

Specifically, the substrate is, for example, made of Si wafer, glass, or the like.

The gate insulation film is, for example, made of silicon oxide, silicon nitride, or aluminum oxide, and formed, for example, by a method such as vapor deposition or CVD. The thickness of the gate insulation film is not particularly limited, but normally selected in the range of 50 to 1,000 nm.

The gate electrode, source electrode and drain electrode are respectively formed with a conductive metal oxide such as tin oxide, zinc oxide, indium oxide, or indium tin oxide (ITO) or a metal such as gold, silver, aluminum, chromium, or nickel, by a method such as vapor deposition, CVD, or sputtering. The thickness of these electrodes is not particularly limited, but, normally, selected independently in the range of 10 to 100 nm.

(Organic Photoelectric Conversion Element)

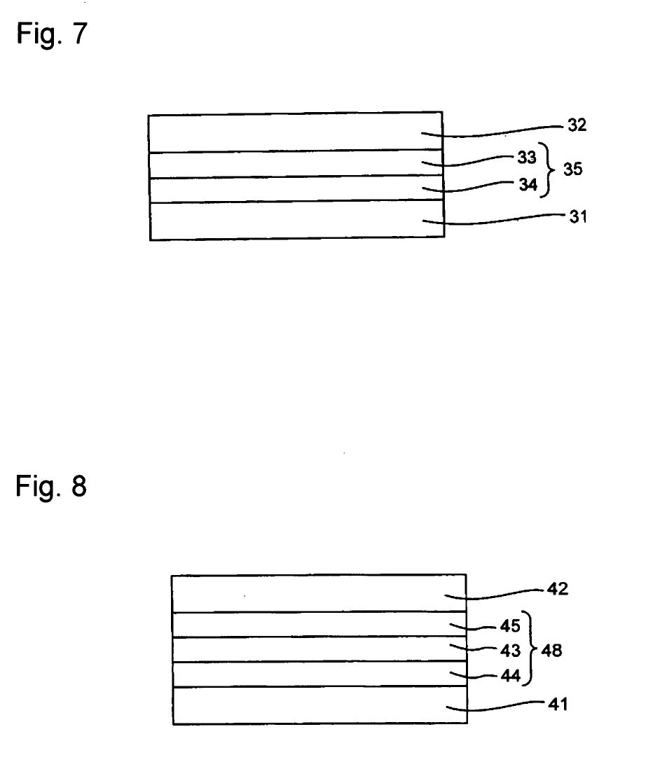

As shown in FIG. 7, the organic photoelectric conversion element has an organic layer 35 between a transparent electrode 31 and a counter electrode 32, and in the present invention, the organic layer 35 is an organic thin film formed by using the organic compound (I).

The organic layer 35 has at least photoconductive layers 33 and 34; the photoconductive layer 35 has an electron-accepting layer 33 functioning as a n-type photoconductive layer and an electron-donating layer 34 functioning as a p-type photoconductive layer for improvement in conversion efficiency, as shown in FIG. 7.

In the photoelectric conversion element according to the present invention, each of the n-type photoconductive layer 33 and the p-type photoconductive layer 34 constituting the organic layer 35 may have a single monomolecular film or multilayer unimolecular film structure, and the organic layer 35 has a multilayer unimolecular film structure as a whole. In the present invention, at least one monomolecular film, preferably all monomolecular films, constituting the organic layer is formed by using the organic compound (I).

Specifically, the n-type photoconductive layer 33 preferably has a monomolecular film structure and is formed with an organic compound (I) (each of A¹ to A⁶ is not particularly limited and may be the same as that described above) having an organic group B derived from a perylene derivative, a perynone derivative, a naphthalene derivative, a fluorine-substituted monocyclic heterocyclic compound, a condensed aromatic compound or a compound having two or more of the compounds above bound to each, in particular derived from a perylene derivative or a fluorine-substituted oligothiophene derivative. When the n-type photoconductive layer 33 has a multilayer unimolecular film structure, all monomolecular films constituting the multilayer film are preferably formed with the organic compound (I) favorable for the single monomolecular film structure, and all monomolecular films may be formed with the same organic compound (I). The thickness of the n-type photoconductive layer is not particularly limited, but preferably 4 to 300 nm, in particular 4 to 100 nm.

The p-type photoconductive layer 34 preferably has a single monomolecular film structure and is formed with an organic compound (I) (each of A¹ to A⁶ is not particularly limited and may be the same as that described above) having an organic group B derived from a monocyclic aromatic compound, a monocyclic heterocyclic compound, a condensed aromatic compound or a compound having two or more of the compounds above bound to each other, in particular derived from a phenylene compound derivative or a thiophene compound derivative. When the p-type photoconductive layer 34 has a multilayer unimolecular film structure, all monomolecular films constituting the multilayer film are preferably formed with the organic compound (I) favorable for the single monomolecular film structure, and all monomolecular films may be formed with the same organic compound (I). The thickness of the p-type photoconductive layer is not particularly limited, but preferably 4 to 300 nm, in particular 4 to 100 nm.

In the organic layer 35 of the photoelectric conversion element according to the present invention, the monomolecular film formed by using the organic compound (I) is bound to the film immediately below or the electrodes via chemical bonds. In particular when all monomolecular films in all layers are formed with the organic compound (I), the all monomolecular films are bound respectively to the films immediately below or the electrodes via chemical bonds.

In the organic layer of photoelectric conversion element, the monomolecular film containing no organic compound (I) may be formed with any organic compound, and, for example, formed with the molecule containing a π-electron-conjugated skeleton, the precursor of the organic group B, exemplified in the description on the organic compound (I).

In preparing the photoelectric conversion element, the monomolecular film of organic compound (I), among the monomolecular film constituting the organic layer 35, is preferably formed according to a method similar to that for forming an organic thin film above. The monomolecular film containing no organic compound (I) may be formed, for example, by a method such as spin coating, casting, dip coating, or LB method.

Any know material traditionally used in the field of photoelectric conversion element may be used for the transparent electrode 31 and the counter electrode 32.

The transparent electrode is preferably, for example, glass or plastic coated with a conductive metal oxide such as ITO.

The counter electrode is preferably, for example, a metal such as platinum, gold or aluminum, or a conductive metal oxide such as ITO.

The thickness of the transparent or counter electrode is not particularly limited, but, normally 50 to 1,000 nm.

(Organic EL Element)

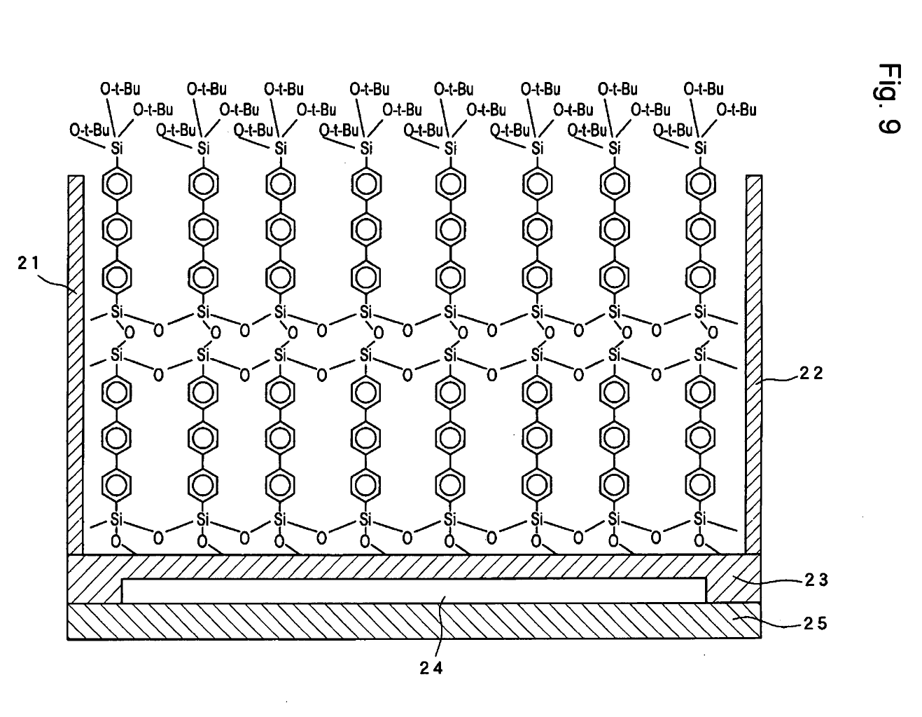

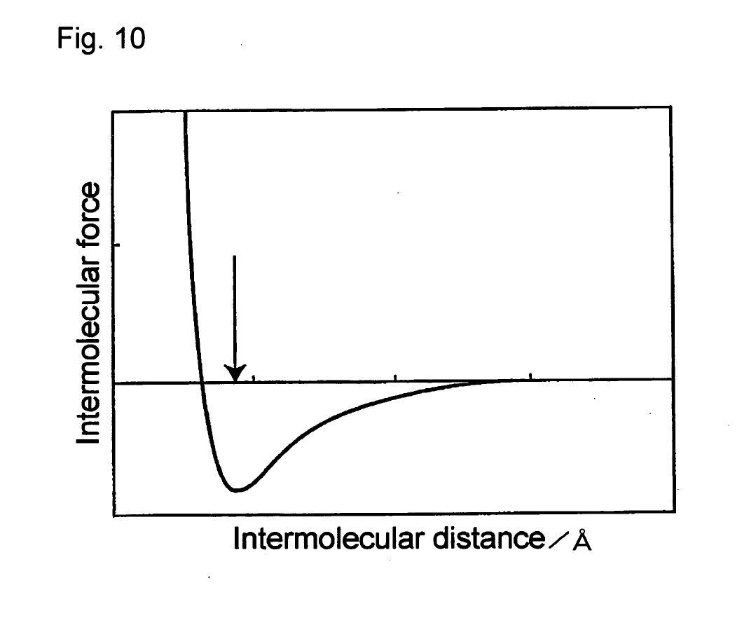

As shown in FIG. 8, the organic EL element has an organic layer 48 between an anode 41 and a cathode 42, and in the present invention, the organic layer 48 is an organic thin film formed by using the organic compound (I).

Specifically, the organic layer 48 has at least a light-emitting layer 43, and may have additionally an electron-transporting layer 45 and a positive hole-transporting layer 44 formed next to the light-emitting layer 43 as needed. The organic layer 48 may have a positive hole-injecting layer (not shown in the Figure) between the anode 41 and the positive hole-transporting layer 44 and an electron-injecting layer (not shown in the Figure) between the cathode 42 and the electron-transporting layer 45 for improvement in luminous efficiency.

In the EL element according to the present invention, the light-emitting layer 43, electron-transporting layer 45, positive hole-transporting layer 44, positive hole-injecting layer and electron-injecting layer constituting the organic layer 48 may respectively have a single monomolecular film or multilayer unimolecular film structure, and the organic layer 48 has a multilayer unimolecular film structure as a whole. In the present invention, at least one monomolecular film, preferably all monomolecular films, constituting the organic layer is formed by using the organic compound (I).

Specifically, the light-emitting layer 43 is a layer in which the positive holes injected from the positive hole-transporting layer 44 and the electrons injected from the electron-transporting layer 45 flow and emit light by recombination of the positive holes and the electron Such a light-emitting layer 43 preferably has a single monomolecular film structure, and is preferably formed with an organic compound (I) (each of A¹ to A⁶ is not particularly limited and may be the same as that described above) having an organic group B derived from a condensed aromatic compound or an oligothiophene derivative, in particular derived from a condensed aromatic compound. When the light-emitting layer has a multilayer unimolecular film structure, all monomolecular films constituting the multilayer film are preferably formed with the organic compound (I) favorable for the layer having a single monomolecular film structure; and all monomolecular films may be formed with the same organic compound (I). The thickness of the light-emitting layer is not particularly limited, but preferably 4 to 300 nm, more preferably 4 to 100 nm.

The positive hole-transporting layer 44 and the positive hole-injecting layer are layers for improving the positive hole-injecting efficiency from the anode 41 to the light-emitting layer 43 and preventing release of electrons to the anode 41. The positive hole-transporting layer 44 and the positive hole-injecting layer preferably have respectively a single monomolecular film structure and are preferably formed with an organic compound (I) (each of A¹ to A⁶ is not particularly limited and may be the same as that described above) having an organic group B derived from a monocyclic heterocyclic compound, a condensed aromatic compound or a compound having two or more of the compounds above bound to each other, in particular derived from a phenylene compound derivative or a thiophene compound derivative. When the positive hole-transporting layer 44 and the positive hole-injecting layer have a multilayer unimolecular film structure, all monomolecular films constituting the multilayer film are preferably formed with the organic compound (I) favorable for the layer having a single monomolecular film structure; and all monomolecular films may be formed with the same organic compound (I). The thickness of the positive hole-transporting layer or the positive hole-injecting layer is not particularly limited, but preferably 4 to 300 nm, in particular 4 to 100 nm.

The electron-transporting layer 45 and the electron-injecting layer are layers for improving the electron-injecting efficiency from the cathode 42 to the light-emitting layer 43. The electron-transporting layer 45 and the electron-injecting layer preferably have respectively a single monomolecular film structure, and is preferably formed with an organic compound (I) (each of A¹ to A⁶ is not particularly limited and may be the same as that described above) having an organic group B derived from a perylene derivative, a perynone derivative, a naphthalene derivative, a fluorine-substituted monocyclic heterocyclic compound, a condensed aromatic compound or a compound having two or more of the compounds above bound to each other, in particular derived from a perylene derivative or a fluorine-substituted oligothiophene derivative. When the electron-transporting layer 45 and the electron-injecting layer have a multilayer unimolecular film structure, all monomolecular films constituting the multilayer film are preferably formed with the organic compound (I) favorable for the layer having a single monomolecular film structure; and all monomolecular films may be formed with the same organic compound (I). The thickness of the electron-transporting layer or the electron-injecting layer is not particularly limited, but preferably 4 to 300 nm, in particular 4 to 100 nm.

The monomolecular film formed by using the organic compound (I) in the organic layer 48 of the EL element according to the present invention is bound to the film immediately below or the electrodes via chemical bonds. In particular when all monomolecular films in all layers are formed by using the organic compound (I), all monomolecular films are bound to the films immediately below or the electrodes via chemical bonds.

The monomolecular film containing no organic compound (I) in the organic layer of EL element may be formed with any organic compound, and, for example, formed with the molecule containing a π-electron-conjugated skeleton, the precursor of the organic group B, exemplified in the description on the organic compound (I).

In preparing the EL element, the monomolecular film of organic compound (I), among the monomolecular films constituting the organic layer 48, is formed by a method similar to that used in the method of forming the organic thin film. The monomolecular film containing no organic compound (I) may be formed, for example, by a method such as spin coating, casting, dip coating, or LB method.

An electrically conductive compound of a metal or alloy higher in positive hole-injecting efficiency and work function is used as the anode 41. Examples of the compounds include gold, copper iodide, tin oxide, ITO, and the like. Among them, materials higher in the transmittance in the visible light region are preferable, and ITO is particularly preferable.

A metal or alloy having a relatively smaller work function (for example, 4 eV or less) is used as the cathode 42. Examples of the compounds include alkali metals, alkali-earth metals and group III metals such as gallium and indium, and the like, but cheaper and relatively more chemically stable magnesium is used most widely. Magnesium is easily oxidized and thus, a mixture thereof with an antioxidant is more preferable.

The thickness of the anode or the cathode is not particularly limited, but preferably 10 nm to 5 μm.

### EXAMPLES

### Experimental Example 1

### Preparative Example 1

### Preparation of Disilylated Quarterthiophene Represented by Formula (a1) (Hereinafter, Referred to as Thiophene (a1))

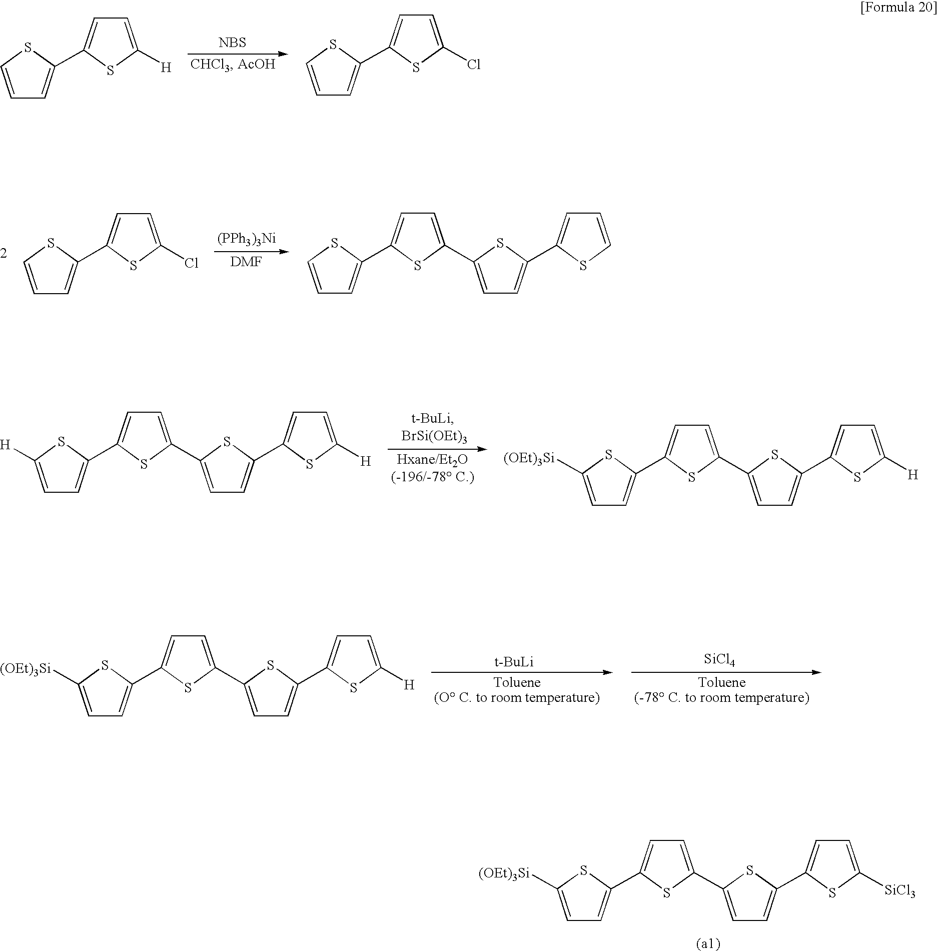

2,2¹-Bithiophene (492-97-7) was chlorinated by treatment with NBS and chloroform in acetic acid (intermediate 1). The chlorinated bithiophene molecules were bound to each other directly at the chlorinated sites in reaction of the chlorinated bithiophenes in DMF solvent in the presence of a catalyst tris(triphenylphosphine)nickel ((PPh₃) 3Ni), to give quarterthiophene.

300 ml of a mixture solution containing 1 equivalence of quarterthiophene and 1 equivalence of triethoxybromosilane (in hexane/diethylether) was placed in a 1-liter glass flask under dry nitrogen stream; 1 equivalence of t-butyllithium was added dropwise from a funnel at −70° C. over 12 hours; and the mixture was heated once to room temperature after dropwise addition and cooled again to −196° C. Distillation of the reaction solution gave a colorless liquid of triethoxysilylated quarterthiophene as distillate.

The triethoxysilylated quarterthiophene obtained was dissolved in toluene solvent, and 1 equivalence of t-butyllithium was added thereto dropwise at 0° C. over 10 hours. After dropwise addition, the mixture was stirred at room temperature for 12 hours, to give a suspension. The suspension was added dropwise into a toluene solution containing 1 equivalence of tetrachlorosilane at −70° C. over 10 hours. After dropwise addition, the flask was removed from the cooling bath, and the mixture was stirred additionally for 6 hours.

The precipitate lithium chloride was removed by filtration, and filtration under reduced pressure gave a compound (a1).

Results obtained by instrumental analysis of the thiophene (a1) are shown below:

¹H NMR (δ CDCl₃): 7.00 ppm (m, 8H, C₄ H₂ S) 3.83 ppm (m, 6H, C₂ H₅) 1.22 ppm (m, 9H, C₂ H₅) UV-Vis: 400 nm (C₄ H₂ S)

The measurement results above confirmed that the compound had a structure represented by the Formula above (a1).

### Preparative Example 2

### Preparation of Disilylated Hexithiophene Represented by Formula (a12) (Hereinafter, Referred to as Thiophene (a12))

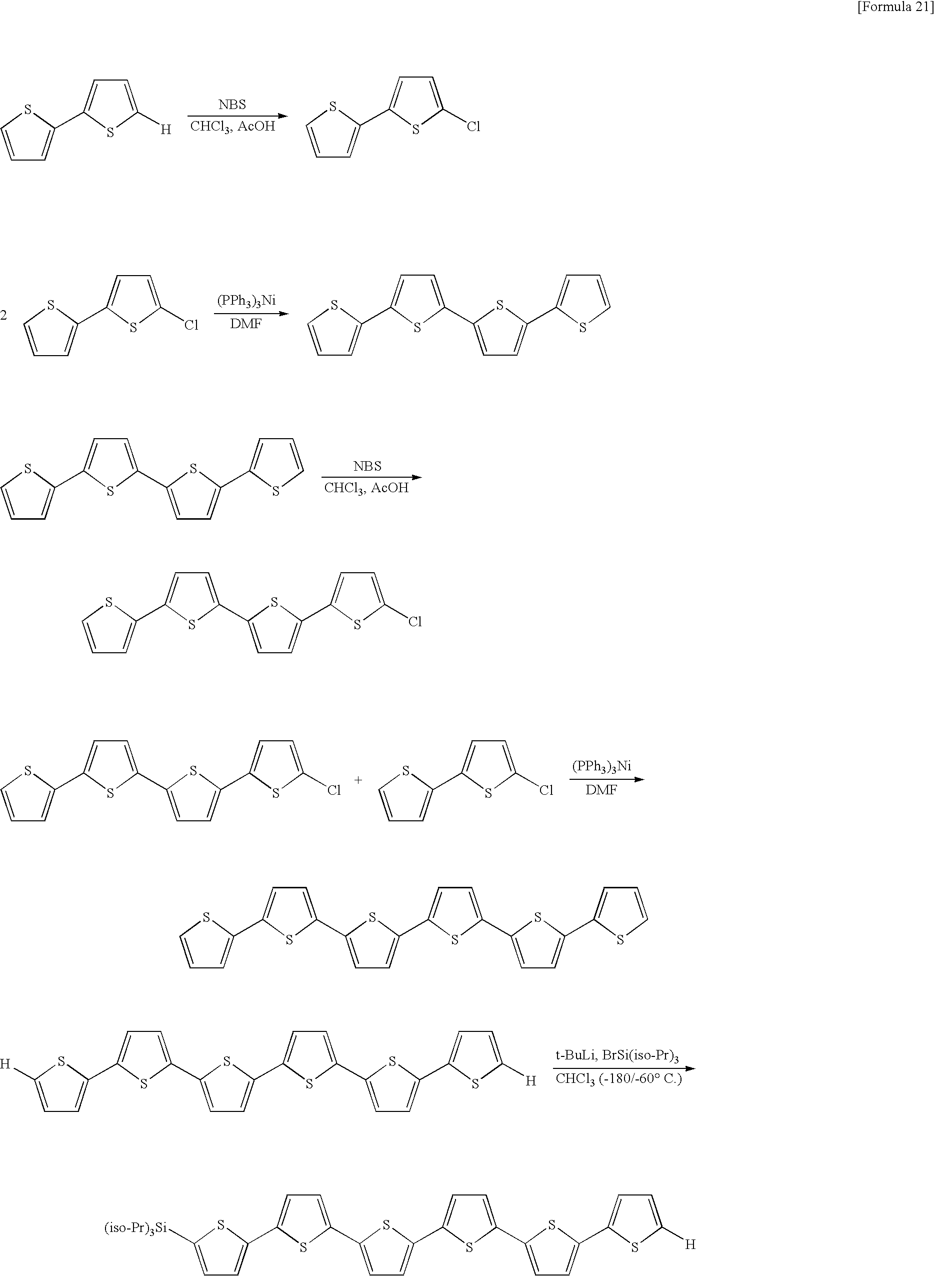

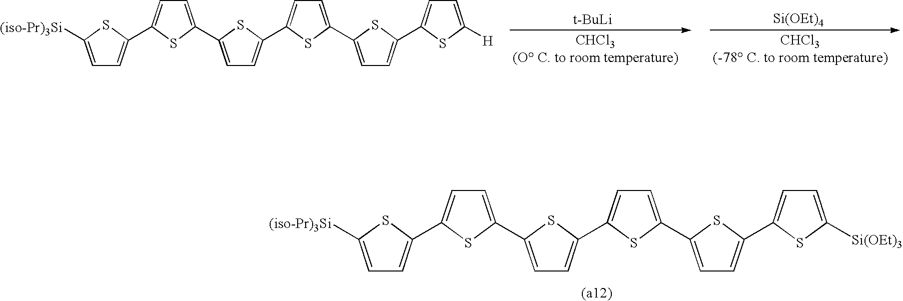

Hexithiophene was prepared by two-phase coupling of bithiophene by using the method described in Preparative Example 1.

300 ml of a chloroform solution containing 1 equivalence of hexithiophene and 1 equivalence of triisopropyl bromosilane was placed in a 1-liter glass flask under dry nitrogen stream; 1 equivalence of t-butyllithium was added thereto dropwise from a funnel at −60° C. over 12 hours; and the mixture was heated once to room temperature after dropwise addition and cooled again to −180° C. Distillation of the reaction solution gave a colorless liquid of triisopropylsilylated hexithiophene as distillate.

The triisopropylsilylated hexithiophene obtained was dissolved in chloroform solvent, and 1 equivalence of t-butyllithium was added thereto dropwise at 0° C. over 10 hours. After dropwise addition, the mixture was stirred at room temperature for 12 hours, to give a suspension. The suspension was added dropwise into a chloroform solution containing 1 equivalence of tetraethoxysilane at −70° C. over 10 hours. After dropwise addition, the flask was removed from the cooling bath, and the mixture was stirred additionally for 6 hours.

The precipitate lithium chloride was removed by filtration, and filtration under reduced pressure gave a compound (a12).

Results obtained by instrumental analysis of the thiophene (a12) are shown below:

¹H NMR (δ CDCl₃): 7.00 ppm (m, 12H, C₄H₂S) 3.83 ppm (m, 6H, OC₂H₅) 1.80 ppm (m, 3H, C₃H₇) 1.22 ppm (m, 9H, OC₂H₅) 0.90 ppm (m, 18H, C₃H₇) UV-Vis: 439 nm (C₄H₂S)

The measurement results above confirmed that the compound had a structure represented by the Formula above (a12).

### Example 1

### Preparation of Single Film of a Thiophene (a1) Monomolecular Film, Single Film of a Thiophene (a12) Monomolecular Film, and Bilayer Film of a Thiophene (a1) Monomolecular Film and a Thiophene (a12) Monomolecular Film

A Si wafer, quartz glass substrate, was immersed in a mixed solution of (hydrogen peroxide/sulfuric acid) and irradiated with UV light for hydrophilizing treatment, and then, washed thoroughly and cleaned with purified water, to give a substrate. Films were formed on the substrate thus obtained.

First, a toluene solution of 0.2 mM thiophene (a1) was spread on the surface of water at pH 7, allowing adsorption thereof onto the substrate associated with release of chlorine atoms of the trichlorosilyl group by the LB method, to form a thiophene (a1) monomolecular film.

Separately, a thiophene (a12) monomolecular film was formed in a similar manner to the method above, except that thiophene (a12) was used and the pH of the lower water layer was adjusted to 2.

Then, a toluene solution of 0.2 mM thiophene (a12) was spread on the surface of water at pH 2, and a multilayer film was formed by coating the thiophene (a12) on the thiophene (a1) monomolecular film prepared in the process above by the LB method. Under the condition of pH 2, the adsorption reaction proceeds, together with hydrolysis of the triethoxysilyll groups in thiophenes (a1) and (a12).

Observation of the surface of the multilayer film at the scale of 50 μm under an atomic force microscope (AFM) (SPA400, manufactured by Seiko Instruments Inc.) revealed that the film was uniform at the scale of 50 μm. In addition, machining of the film by mechanical treatment showed that the film thickness was close to the sum of the molecular lengths of quarterthiophene and hexithiophene, 6 nm. The results above indicated that a bilayer monomolecular film uniform in film thickness was formed.

The ultraviolet-visible absorption spectra of the single film of thiophene (a1) monomolecular film and the bilayer monomolecular film of thiophenes (a1) and (a12) were obtained by (UV-3000; manufactured by Shimadzu Corporation), for detailed evaluation of the lamination state of the film. As a result, the thiophene (a1) monomolecular film had absorption at around 350 nm, and the bilayer monomolecular film of thiophenes (a1) and (a12) at around 350 and 410 nm. The results indicate that the film has two layers laminated.

Crystalline orientation in the bilayer monomolecular film was evaluated, based on electron-beam diffraction (ED) measurement by using “H-7500, manufactured by Hitachi. Ltd”. A single film only of thiophene (a1) monomolecular film, a single film only of thiophene (a2) monomolecular film, and a bilayer monomolecular film of thiophenes (a1) and (a2) were used as samples. The substrate used in the ED measurement was a copper mesh sheet having an Formval film adhered as the supporting film that is vapor-deposited with SiO₂ for surface hydrophilization. As a result, the thiophene (a1) monomolecular film gave diffraction spots equivalent to spacings of 0.40 and 0.34 nm, while the bilayer monomolecular film of thiophenes (a1) and (a12) gave diffraction spots equivalent to spacing of 0.40 and 0.34 nm as well as 0.42 and 0.36 nm. The results indicated that an ordered film higher in crystalline orientation was obtained not only in the single film but also in bilayer monomolecular film.

### Example 2

### Preparation of a Single Film and Bilayer to Pentalayer Films of Thiophene (a1) Monomolecular Film

The hydrophilic substrate prepared by the method described in Example 1 was immersed in a toluene solution of 0.01 mM thiophene (a1) at room temperature for 12 hours. A monomolecular film of the bottom layer was formed, by adsorption of the thiophene (a1) molecule in reaction of the hydroxyl groups present on the substrate surface and trichlorosilyl groups. The substrate obtained was cleaned with an organic solvent for removal of the residual unreacted thiophene (a1). The cleaned substrate was immersed in purified water at pH 4, hydrolyzing the triethoxysilyll groups into trihydroxysilyl groups. Then, the monomolecular film-formed substrate ended by the hydroxysilyl-group terminal was immersed in a toluene solution of 0.01 mM thiophene (a1) at room temperature for 12 hours. The second-layer monomolecular film was formed on the monomolecular film of bottom layer, in adsorption reaction of the hydroxysilyl groups present on the film surface of the monomolecular film of bottom layer and the trichlorosilyl groups in the solution. The process of forming the second monomolecular film was repeated third time, to give a pentalayer film having five layers of the thiophene (a1) monomolecular films.

For evaluation of the film thickness and the periodicity of absorption properties and crystalline orientation according to the number of the layered films, these films were analyzed by AFM observation, ultraviolet-visible absorption spectrum measurement and ED measurement, respectively in similar manners to Example 1. As a result, AFM observation revealed that the film thickness increased approximately by 3 nm after formation of an additional layer, and UV-Vis absorption spectrum measurement revealed that the intensity of the absorbance corresponding to π−π* transition increased linearly along with increase in film thickness, indicating that the films are layered sequentially. ED measurement of each film in the single monomolecular film to the pentalayer monomolecular film showed diffraction spots corresponding to spacings of 0.40 and 0.34 nm, indicating that a highly oriented multilayer film was formed without deterioration in film crystalline orientation by lamination of the films.

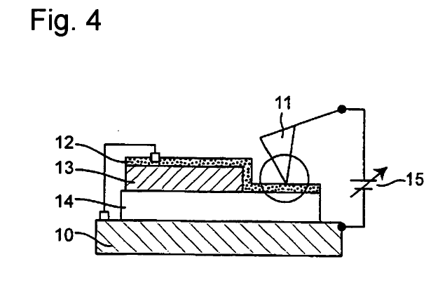

Electrical properties of the single film and the bilayer to pentalayer films were evaluated, based on in-plane electrical AFM measurement. FIG. 4 is a schematic view illustrating the measurement system. The electrical properties were evaluated, by using mica having comb-lobe-shaped electrodes prepared by vapor deposition of gold/chromium to a thickness of dozens nm as the substrate. In the Figure, 10 represents a piezoelectric element in the SPM system; 11 represents a cantilever; 12 represents a single or multilayer film; 13 represents a gold/chromium electrode; 14 represents a mica substrate; and 15 represents an ammeter.

Electric current properties at the electrode interface in the plane direction improve as the number of the films increases, and the current characteristics of the pentalayer film was significantly higher at approximately 40⁻³ S·cm⁻¹, in contrast to that of the single film at approximately 10⁻⁴ S·cm⁻¹. Thus by preparing a multilayer film higher in orientation, it was possible to improve the electrical properties, indicating that lamination of monomolecular films by using the compound according to the present invention was useful in controlling the film thickness for improvement in performance of the organic device.

### Experimental Example 2

### Preparative Example 3

### Preparation Disilylated Terphenyl Represented by Formula (b5) (Hereinafter, Referred to as Terphenyl (b5))

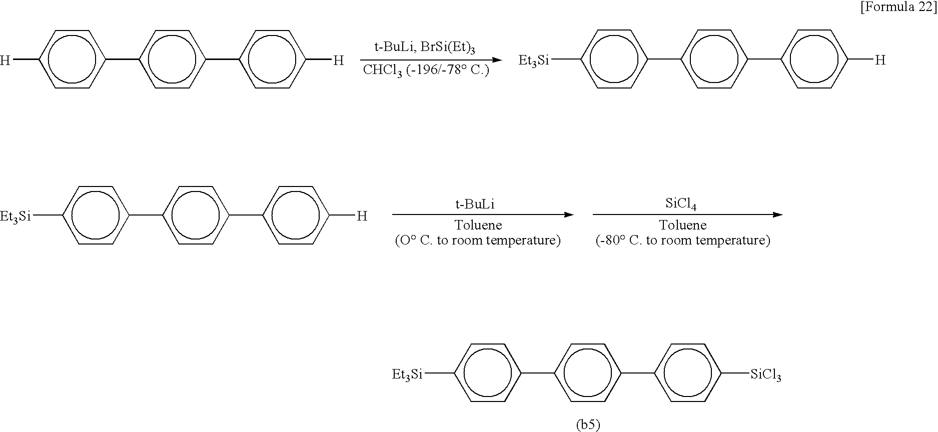

300 ml of a chloroform solution containing 1 equivalence of terphenyl and 1 equivalence of triethyl bromosilane was placed in a 1-liter glass flask under dry nitrogen stream; 1 equivalence of t-butyllithium was added thereto dropwise from a funnel at −70° C. over 12 hours; and the mixture was once heated to room temperature after dropwise addition and cooled again to −196° C. Distillation of the reaction solution gave a colorless liquid of triethylsilylated terphenyl as distillate.

The triethylsilylated terphenyl obtained was dissolved in toluene solvent, and 1 equivalence of t-butyllithium was added thereto dropwise at 0° C. over 10 hours. After dropwise addition, the mixture was stirred at room temperature for 12 hours, to give a suspension. The suspension was added dropwise into a toluene solution containing 1 equivalence of tetrachlorosilane at −70° C. over 10 hours. After dropwise addition, the flask was removed from the cooling bath, and the mixture was stirred additionally for 6 hours.

The precipitate lithium chloride was removed by filtration, and filtration under reduced pressure gave a compound (b5).

Results obtained by instrumental analysis of the terphenyl (b5) are shown below:

¹H NMR (δ CDCl₃): 7.30 to 7.54 ppm (m, 12H, C₆H₆) 1.49 ppm (m, 6H, C₂H₅) 0.90 ppm (m, 9H, C₂H₅) UV-Vis: 261 nm (Ph)

The measurement results above confirmed that the compound had a structure represented by the Formula above (b5).

### Preparative Example 4

### Preparation of Disilylated Terphenyl Represented by Formula (b8) (Hereinafter, Referred to as Terphenyl (b8))

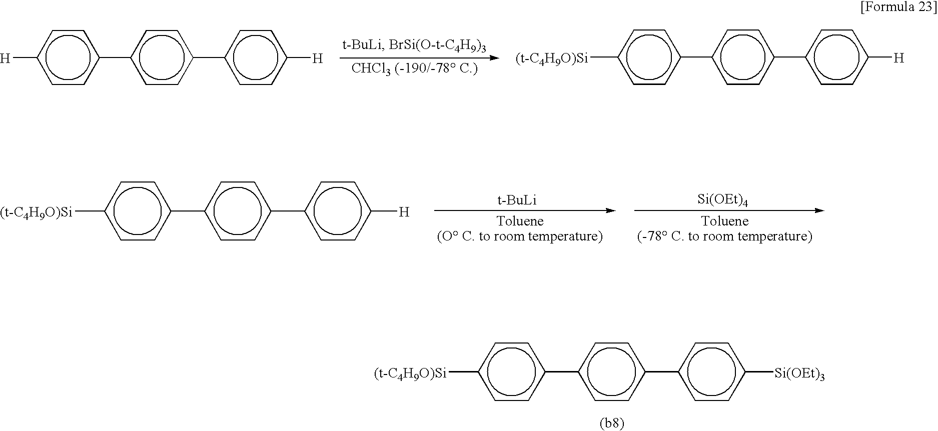

300 ml of a chloroform mixture solution containing 1 equivalence of terphenyl and 1 equivalence of tri-t-butoxybromosilane was placed in a 1-liter glass flask under dry nitrogen stream; 1 equivalence of t-butyllithium was added dropwise from a funnel at −70° C. over 12 hours; and the mixture was heated once to room temperature after dropwise addition and cooled again to −190° C. Distillation of the reaction solution gave a colorless liquid of tri-t-butoxylsilylated terphenyl as distillate.

The tri-t-butoxysilylated terphenyl obtained was dissolved in toluene solvent, and 1 equivalence of t-butyllithium was added dropwise thereto at 0° C. over 10 hours. After dropwise addition, the mixture was stirred at room temperature for 12 hours, to give a suspension. The suspension was added dropwise into a toluene solution containing 1 equivalence of tetrachlorosilane at −80° C. over 10 hours. After dropwise addition, the flask was removed from the cooling bath, and the mixture was stirred additionally for 6 hours.

The precipitate lithium chloride was removed by filtration, and filtration under reduced pressure gave terphenyl (b8).

Results obtained by instrumental analysis of the terphenyl (b8) are shown below:

¹H NMR (δ CDCl₃): 7.30 to 7.54 ppm (m, 12H, C₆H₆) 3.83 ppm (m, 6H, C₂H₅) 1.32 ppm (m, 6H, OC₄H₉) 1.22 ppm (m, 9H, C₂H₅) UV-Vis: 259 nm (Ph)

The measurement results above confirmed that the compound had a structure represented by the Formula above (b8).

### Example 3

### Formation of a Bilayer Film of a Terphenyl (b5) Monomolecular Film and a Terphenyl (b8) Monomolecular Film

A Si wafer, quartz glass substrate, was immersed in a mixed solution of (hydrogen peroxide/sulfuric acid) and irradiated with UV light for hydrophilizing treatment, and washed thoroughly and cleaned with purified water, to give a substrate.

A toluene solution of 0.2 mM terphenyl (b5) was spread on the surface of water at pH 7 and a water temperature of 40° C., allowing adsorption onto the silanol groups on the substrate surface associated with release of chlorine atoms of the trichlorosilyl group by the LB method, to form a terphenyl (b5) monomolecular film. The film formed was washed with an organic solvent and dried. Observation of the surface shape of the terphenyl (b5) monomolecular film under an atomic force microscope (AFM) and the difference in height between the substrate and film by mechanical machining of the film indicated preparation of a terphenyl (b5) monomolecular film. Separately, ultraviolet-visible absorption spectrum measurement showed absorption at 290 nm corresponding to the π−π* transition of terphenyl, indicating that the monomolecular film was formed with terphenyl (b5).

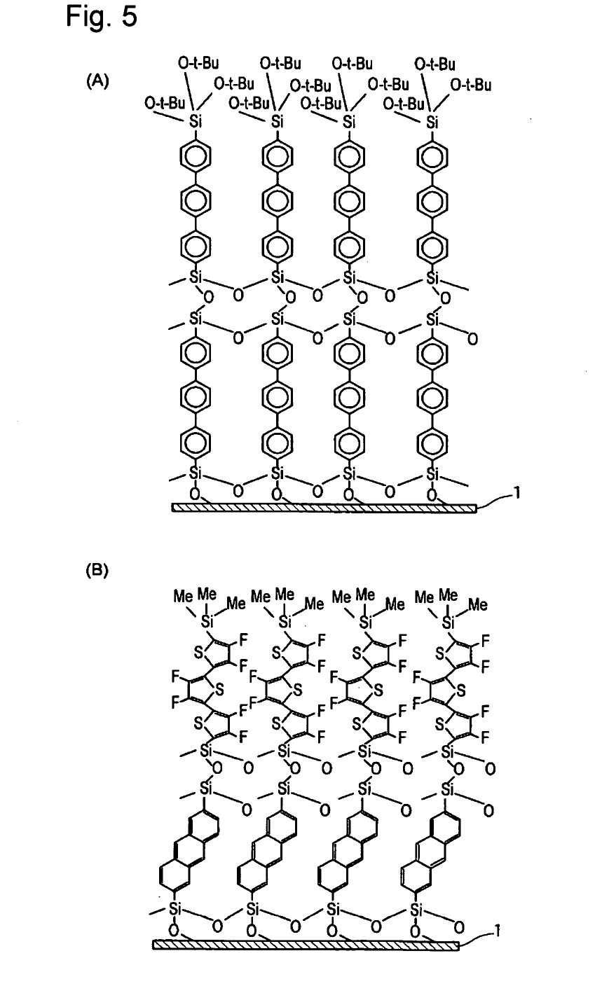

Then, a toluene solution of 0.2 mM terphenyl (b8) was spread on the surface of water at pH 4 and a water temperature of 40° C.; and the terphenyl layer was formed on the terphenyl (b5) monomolecular film prepared in the process above by the LB method, to give a multilayer film in which the terphenyl layers are bound to each other via silanol bonds, as shown in FIG. 5(A).

Observation of the film surface shape under an atomic force microscope (AFM) at a resolution of 50 μm in a similar manner to Example 1 revealed that the film was formed uniformly at the scale of 50 μm. In addition, machining of the film by mechanical treatment showed that the film thickness was close to the sum of the molecular lengths, approximately 4 nm. The results above indicated that a bilayer film uniform in film thickness was formed.

The crystal structure of the bilayer film was evaluated based on the electron beam diffraction (ED) measurement by a method similar to that in Example 1. The substrate used in the ED measurement was a Formval film vapor-deposited with SiO₂. As a result, diffraction spots corresponding to the phenylene crystal structure were observed with the bilayer film. The results indicate that both terphenyls (b5) and (b8) give respectively monomolecular films having highly ordered crystalline orientation.

### Example 4

### Preparation of Organic Thin-film Transistor and Evaluation of the Electrical Properties

An organic thin-film transistor of FIG. 9 was prepared.

First, chromium and gold are vapor-deposited on a silicon substrate 25, to form a gate electrode 24. Then, a gate insulation film 23 of silicon oxide film was deposited thereon by chemical gas-phase adsorption. Chromium and gold were further deposited through a mask, to form a source electrode 21 and a drain electrode 22.

The substrate with the electrodes formed was irradiated with ultraviolet light, hydrophilizing the surface of the gate insulation film 23. A bilayer film consisting of terphenyl (b5) and (b8) monomolecular films was formed in a similar manner to Example 3, except that the substrate obtained was used, to give the organic thin-film transistor shown in FIG. 9.

The field-effect mobility and the on/off ratio thereof were determined, for evaluation of the electrical properties of the transistor. The electric current flowing between the source and drain electrodes was measured, while changing the voltage applied thereto by varying the negative gate voltage (4155A; manufactured by Hewlett-packard Company). As a result, the field-effect mobility was shown to be approximately 4×10⁻² cm²V⁻¹s⁻, and the on/off ratio was approximately a 5-digit number. The results above showed that the multilayer unimolecular film containing different kinds of π-electron-conjugated organic compounds was improved in the uniformity, orientation, and crystallinity as well as the electrical properties of film.

### Comparative Example 1

A transistor was prepared in a similar manner to Example 4, except that the terphenyl (b5) and terphenyl (b8) were replaced with terphenyltriethoxysilane.

The electrical properties of the transistor obtained were evaluated by a method similar to that in Example 4. The results showed that the field-effect mobility was approximately 1×10⁻² cm²V⁻¹s⁻¹ and the on/off ratio approximately a 4-digit number, indicating that the transistor of Example 4 was extremely superior in electrical properties.

### Experimental Example 3

### Preparative Example 5

### Preparation of Disilylated Anthracene Represented by Formula (c1) (Hereinafter, Referred to as Anthracene (c1))

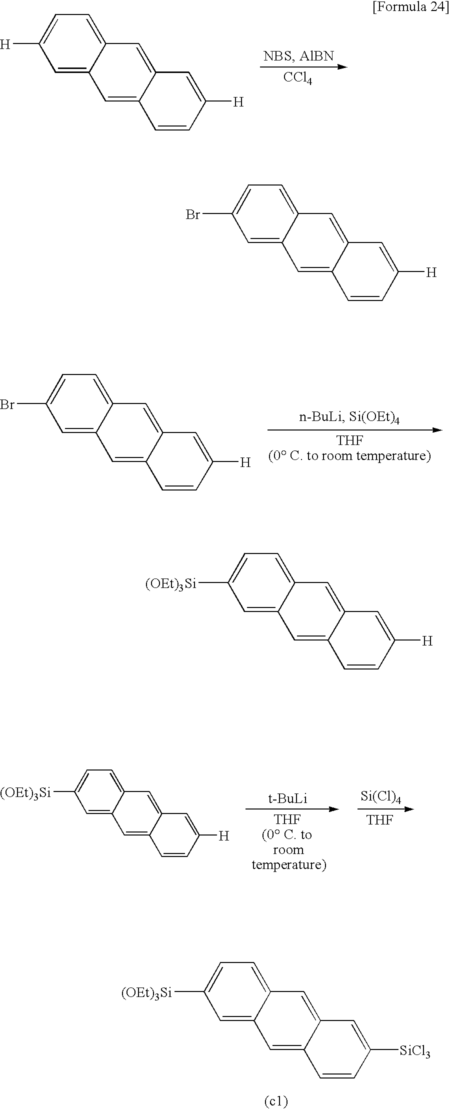

Anthracene (120-12-7) was purchased from Tokyo Chemical Industry CO., LTD.

Silane Coupling Reaction

One equivalence of anthracene dissolved in 50 mL of carbon tetrachloride and NBS were placed in a 100 ml egg plant flask under nitrogen environment, and the mixture was allowed to react in the presence of AIBN for 1.5 hours. After removal of the unreacted material and HBr by filtration, monobrominated products were separated by column chromatography; and the products were further purified by column chromatograph, to give the title compound 1-bromoanthracene.

One equivalence of 1-bromoanthracene was dissolved in 30 ml of THF solution, and 1 equivalence of n-BuLi was added gradually, dropwise at 0° C. over 10 hours. The mixture solution was stirred for 4 hours and then warmed to room temperature. The deep green solution obtained in the reaction was added dropwise to a THF solution of one equivalence of tetraethoxysilane at room temperature, and the mixture was heated and mixed under reflux for 15 hours. Then, the reaction solution was filtered under reduced pressure, removing unreacted tetraethoxysilane and n-BuLi, to give 1-triethoxysilyllanthracene.

One equivalence of 1-triethoxysilyllanthracene was dissolved in 30 ml of THF, and 1 equivalence of n-BuLi was added gradually thereto, dropwise at 0° C. over 10 hours. The mixed solution was stirred for 4 hours and then warmed to room temperature. The deep green solution obtained in the reaction was added dropwise to a THF solution of one equivalence of tetrachlorosilane at room temperature, and the mixture was heated and mixed under reflux for 15 hours. Then, the reaction solution was filtered under reduced pressure, removing the unreacted tetraethoxysilane and n-BuLi, and the products were purified by column chromatography, to give anthracene (c1).

Results obtained by instrumental analysis of the anthracene (c1) are shown below:

¹H NMR (δ CDCl₃): 8.30 to 7.40 ppm (m, 8H, C₁₄H₈) 3.83 ppm (m, 6H, OC₂H₅) 1.22 ppm (m, 9H, OC₂H₅) UV-Vis: 375 nm (C₁₄H₈)

The measurement results above confirmed that the compound had a structure represented by the Formula above (c1).

### Preparative Example 6

### Preparation of Fluorinated Terthiophene Represented by Formula (f1) (Hereinafter, Referred to as Fluoroterthiophene (f1))

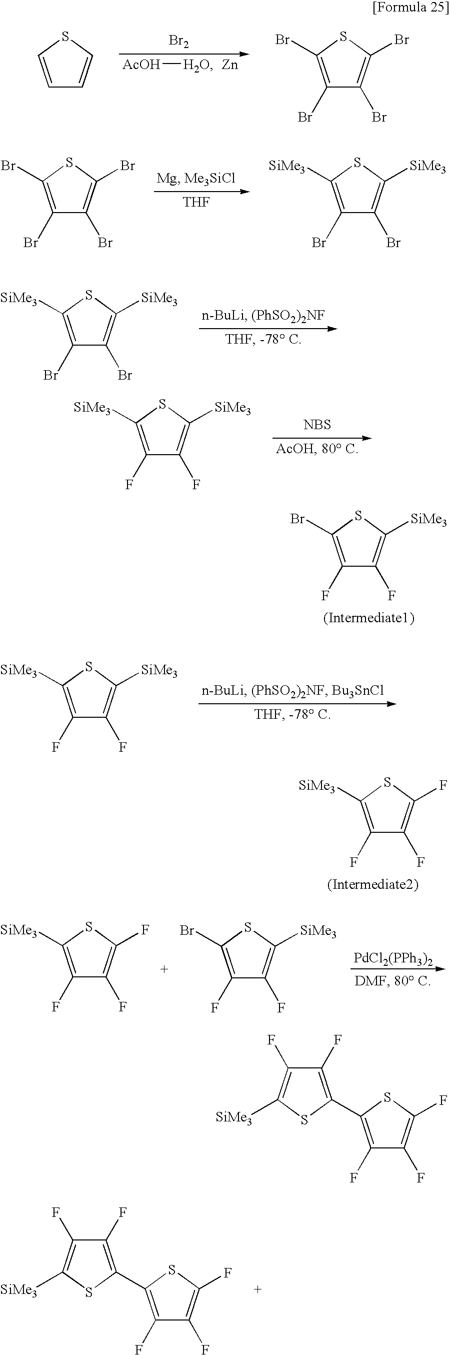

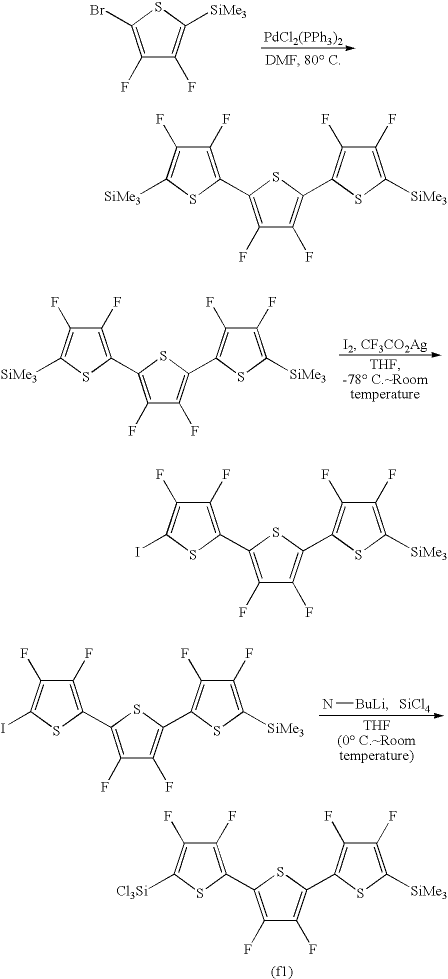

All reactions were carried out under nitrogen atmosphere. One equivalence of thiophene was mixed with bromine in an acetic acid solution containing zinc as a catalyst under reflux, to give 2,3,4,5-tetrabromothiophene. Then, magnesium and trimethylchlorosilane were added to a THF solution so that 2,3,4,5-tetrabromothiophene, magnesium, and trimethylchlorosilane could be contained at a molar ration of 1:2.5:2.5, and the mixture was ultrasonicated for four days. The 2,5-ditrimethylsilyl-3,4-dibromothiophene obtained was added to a THF solution containing phenylsulfonyl nitrogen fluoride ((PhSO₂)₂NF) and n-butyllithium, and the mixture was allowed to react at −70° C., to convert the dibromo compound to its difluoro compound. The products after reaction were treated with NBS in acetic acid at 80° C., brominating the trimethylsilyl group (intermediate 1). Separately, 2,5-Ditrimethylsilyl-3,4-difluorothiophene was treated with n-butyllithium, (PhSO₂)₂ NF, and tributyltin chloride (Bu₃SnCl) at −70° C., allowing fluorination of the trimethylsilyl group at the 2 position, to give 2,3,4-trifluoro-5-trimethylsilyl-thiophene (intermediate 2). The intermediates 1 and 2 was allowed to react in a liquid mixture of PdCl₂(PPh₃)₂ and DMF at 80° C., to give 2-trimethylsilyl-3,4,7,8,9-pentafluoro-bithiophene. The product obtained and the intermediate 1 were allowed to react by a reaction mechanism similar to that above, to give terthiophene having trimethylsilyl groups at both terminals. The terthiophene was mixed in a THF solution; the mixture was cooled to −70° C. in a dry ice/acetone bath; and 2 equivalences of silver trifluoroacetate was added dropwise; and the mixture was stirred for 5 minutes for complete solubilization. Then, a THF solution containing 2 equivalences of iodine was added dropwise, and the mixture was stirred at −70° C. for 8 hours, and then warmed to room temperature, to give 2-trimethylsilyl-3,4,7,8,11,12-sexifluoro-13-iodo-terthiophene. One equivalence of the product obtained was dissolved in 30 ml of THF solution, and 1 equivalence of n-BuLi was added gradually, dropwise at 0° C. over 10 hours. The mixture solution was stirred for 4 hours and then warmed to room temperature. The solution obtained after reaction was added dropwise to a THF solution containing 1 equivalence of tetrachlorosilane at room temperature, and the mixture was heated and mixed under reflux for 15 hours. Then, the reaction solution was filtered under reduced pressure, for removal of unreacted 2-trimethylsilyl-3,4,7,8,11,12-sexifluoro-13-iodo-terthiophene and n-BuLi, and the products were purified by column chromatograph, to give fluoroterthiophene (f1).

Results obtained by instrumental analysis of the fluoroterthiophene (f1) are shown below:

¹H NMR (δ CDCl₃): 1.49 ppm (m, 9H, CH₃) UV-Vis: 365 nm (C₄ H₂ S)

The measurement results above confirmed that the compound had a structure represented by the Formula above (f1).

### Example 5

### Formation of a Bilayer Film of an Anthracene (c1) Monomolecular Film and Fluoroterthiophene (f1) Monomolecular Film

A Si wafer, quartz glass substrate, was immersed in a mixed solution of (hydrogen peroxide/sulfuric acid) and irradiated with UV light for hydrophilizing treatment, and washed thoroughly and cleaned with purified water, to give a substrate.

A toluene solution of 0.2 mM anthracene (c1) was spread on the surface of water at pH 7 and a water temperature of 40° C., allowing adsorption thereof onto the silanol groups on the substrate surface associated with release of chlorine atoms of the trichlorosilyl group by the LB method, to form an anthracene (c1) monomolecular film. The film obtained was washed with an organic solvent and dried. Observation of the surface shape of the anthracene (c1) monomolecular film under an atomic force microscope (AFM) and the difference in height between the substrate and film by mechanical machining of the film indicated preparation of an anthracene (c1) monomolecular film. In addition, ultraviolet-visible absorption spectrum measurement showed absorption at 370 nm corresponding to the π−π* transition of anthracene, indicating that the monomolecular film was formed with anthracene (c1).

Then, a toluene solution of 0.2 mM fluoroterthiophene (f1) was spread on the surface of water at pH 4 and a water temperature of 40° C., forming its film on the anthracene (c1) monomolecular film formed in the process above by the LB method, to give a multilayer film wherein the respective layers are bound via silanol bonds, as shown in FIG. 5(B).

Observation of the film surface shape under an atomic force microscope (AFM) at a resolution of 50 μm in a similar manner to Example 1 revealed that the film was formed uniformly at the scale of 50 μm. In addition, machining of the film by mechanical treatment showed that the film thickness was close to the sum of the molecular lengths, approximately 3.5 nm. The results above indicated that a bilayer film uniform in film thickness was formed.

The crystal structure of the bilayer film was evaluated, based on the electron beam diffraction (ED) measurement by a method similar to that in Example 1. The substrate used in the ED measurement was a Formval film vapor-deposited with SiO₂. As a result, diffraction spots corresponding to the anthracene and terthiophene crystal structures were observed with the bilayer film. The results indicate that both anthracene (c1) and fluoroterthiophene (f1) each independently give monomolecular films having highly ordered crystalline orientation.

### Example 6

### Preparation of Organic Photoelectric Conversion Element and Evaluation of the Electrical Properties

By using an ITO substrate previously surface-irradiated with ultraviolet light and hydrophilized as an anode, a multilayer film shown in Example 5 consisting of anthracene (c1) and fluoroterthiophene (f1) monomolecular films was formed on the ITO substrate by the LB method, in the order of p-type anthracene (c1) film and n-type fluoroterthiophene (f1) film thereon. Gold was deposited to a thickness of 40 nm under a vacuum of 10⁻³ on the ITO glass/(c1)/(f1) film, to give a photoelectric conversion element cell having an effective area of 20×10 mm². A light from a 500W xenon lamp was irradiated on the ITO-electrode sided surface of the photoelectric conversion element cell obtained, and the open voltage Vo, short-circuit current Io, fill factor FF and photoelectric conversion efficiency μ thereof were determined, respectively to be 80 mV, 44 μA/cm², 0.45 and 4.3%.

### Comparative Example 2

A photoelectric conversion element was prepared in a similar manner to Example 6, except that the anthracene (c1) used was replaced with anthracene having no terminal silyl group and the fluoroterthiophene (f1) with fluoroterthiophene having no terminal silyl group.

The electrical properties of the photoelectric conversion element obtained were determined in a similar manner to Example 6. As a result, the Voc, Io, FF and μ values were respectively 45 mV, 13 μA/cm², 0.13 and 1.1%, indicating that the photoelectric conversion element of Example 6 was significantly superior in electrical properties.

Experimental Example 4

### Preparative Example 7

### Preparation of Disilylated Alkane Represented by Formula (d1) (Hereinafter, Referred to as Alkane (d1))

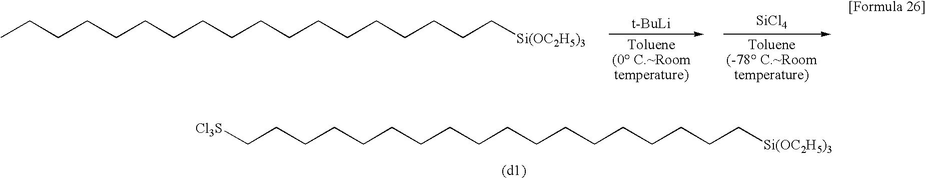

Octadecyl triethoxysilane (OTES, CAS No.7399-00-0) was purchase from Tokyo Chemical Industry CO., LTD. Alkane (d1) was prepared with the OTES purchased.

OTES was dissolved in toluene solvent, and 1 equivalence of t-butyllithium was added dropwise at 0° C. over 10 hours. After dropwise addition, the mixture was stirred at room temperature for 12 hours, to give a suspension. The suspension was added dropwise to a toluene solution containing 1 equivalence of tetrachlorosilane at −70° C. over 10 hours. After dropwise addition, the flask was removed from the cooling bath, and the mixture was stirred additionally for 6 hours.

The precipitate lithium chloride was removed by filtration, and filtration under reduced pressure gave a compound alkane (d1).

Results obtained by instrumental analysis of the alkane (d1) are shown below:

¹H NMR (δ CDCl₃): 3.83 ppm (m, 6H, C₂H₅) 1.3 ppm (m, 4H, C₁₈H₃₆) 1.29 ppm (m, 30H, C₁₈H₃₆) 1.22 ppm (m, 9H, C₂H₅) 0.58 ppm (m, 2H, C₁₈H₃₆)

The measurement results above confirmed that the compound had a structure represented by the Formula above (d1).

It was also confirmed that it was possible to disilylate long chain alkanes having 19 to 36 carbon atoms by a similar method.

### Example 7

### Formation of Alkane (d1) Monomolecular Film

A Si wafer, quartz glass substrate, was immersed in a mixed solution of (hydrogen peroxide/sulfuric acid) and irradiated with UV light for hydrophilizing treatment, and washed thoroughly and cleaned with purified water, to give a substrate.

A toluene solution of 0.2 mM alkane (d1) was spread on the surface of water at pH 2 and a water temperature of 24° C., allowing adsorption thereof onto the silanol groups on the substrate surface associated with release of chlorine atoms of the trichlorosilyl group by the LB method, to form an alkane (d1) monomolecular film. The film obtained was washed with an organic solvent and dried. Observation of the surface shape of the alkane (d1) monomolecular film under an atomic force microscope (AFM) and the difference in height between the substrate and film by mechanical machining of the film indicated preparation of an alkane (d1) monomolecular film. Infrared absorption spectrum measurement showed absorption 2,890 and 2,920 cm⁻¹ corresponding to symmetrical-reverse symmetrical stretching vibration of alkane (d1) CH₂, indicating that the monomolecular film was formed with the alkane (d1).

Then, a toluene solution of 0.2 mM fluoroterthiophene (f1) was spread on the surface of water at pH 4 and a water temperature of 40° C., forming its film on the alkane (d1) monomolecular film formed in the process above by the LB method, to give a multilayer film wherein the respective layers are bound via silanol bonds, as shown in FIG. 5(B).

Observation of the film surface shape under an atomic force microscope (AFM) at a resolution of 50 μm in a similar manner to Example 1 revealed that the film was formed uniformly at the scale of 50 82 m. In addition, machining of the film by mechanical treatment showed that the film thickness was close to the sum of the molecular lengths, approximately 4.8 nm. The results above indicate that a bilayer film uniform in film thickness was formed.

The crystal structure of the bilayer film was evaluated, based on the electron beam diffraction (ED) measurement by a method similar to that in Example 1. The substrate used in the ED measurement was a Formval film vapor-deposited with SiO₂. As a result, diffraction spots corresponding to the alkane and terthiophene crystal structures were observed with the bilayer film. The results indicate that both alkane (d1) and fluoroterthiophene (f1) each independently give monomolecular films having highly ordered crystalline orientation.

### Experimental Example 5

### Preparative Example 8

### Preparation of Trichlorosilane-terthiophene-triethoxysilane Represented by Formula (a2) by Grignard Method

Two moles of metal magnesium and 300 ml of toluene solution were placed in a 1-liter glass flask equipped with a stirrer, a reflux condenser, a thermometer, and a dropping funnel under dry argon stream; 0.5 mole of terthiophene was added dropwise from the dropping funnel at around 10° C. over 12 hours; and, after dropwise addition, the mixture was aged at 15° C. for 4 hours, to give a Grignard reagent.

Two moles of metal magnesium, 300 ml of toluene solution and 2.0 moles of tetraethoxysilane were placed in a flask equipped with a reflux condenser, a stirrer, a thermometer, and a dropping funnel under dry argon stream; the Grignard reagent obtained was cooled to 0° C. and added dropwise from the dropping funnel over 12 hours; and after dropwise addition, the mixture was aged at room temperature for 2 hours. The reaction solution was filtered under reduced pressure, removing magnesium, to give triethoxysilane-terthiophene.

Two moles of tetrachlorosilane and 300 ml of tetrahydrofuran (THF) were placed in a 1-liter glass flask equipped with a stirrer, a reflux condenser, a thermometer, and a dropping funnel under dry argon stream; the triethoxysilane-terthiophene obtained was added dropwise at an internal temperature of 25° C. or lower over 2 hours; and after dropwise addition, the mixture was aged at 30° C. for 1 hour. Then, the reaction solution was filtered under reduced pressure, removing magnesium chloride; THF and unreacted tetrachlorosilane were stripped off from the filtrate; and the solution was distilled, to give the compound represented by Formula (a2).

Results obtained by instrumental analysis of the compound are shown below:

¹H NMR (δ CDCl₃): 7.63 to 7.78 ppm (m, C₄H₂S) 2.20 ppm (m, C₂H₅)

The measurement results above confirmed that the compound was the trichlorosilane-terthiophene-triethoxysilane represented by Formula (a2).

The compound in the present Preparative Example was prepared in a similar manner to the first method described above.

### Experimental Example 6

### Preparative Example 9

### Preparation of Trichlorosilane-biphenyl-trimethoxysilane Represented by Formula (b10)

Two moles of metal lithium and 300 ml of THF were placed in a 1-liter glass flask equipped with a stirrer, a reflux condenser, a thermometer, and a dropping funnel under dry argon stream; 0.5 mole of 1-iodo-4-chlorobiphenyl was added dropwise at an internal temperature of −10° C. over 12 hours; and, after dropwise addition, the mixture was aged at room temperature for 4 hours, to give 4-chlorobiphenyllithium.

Three moles of tetrachlorosilane and 300 ml of THF were placed and ice-cooled in a 1-liter glass flask equipped with a stirrer, a reflux condenser, a thermometer, and a dropping funnel under dry argon stream; the 4-chlorobiphenyllithium obtained was added dropwise at an internal temperature of 20° C. or lower over 2 hours; and, after dropwise addition, the mixture was allowed to react at 20° C. Then, the reaction solution was filtered under reduced pressure, removing the unreacted lithium, and THF and unreacted tetrachlorosilane were separated from the filtrate, to give 1-trichlorosilane-4-chlorobiphenyl.

For preparing a Grignard reagent once again with the 1-trichlorosilane-4-chlorobiphenyl obtained, metal magnesium was allowed to react at an internal temperature of 10° C., to give 1-trichlorosilane-4-biphenylmagnesium, which in turn was allowed to react with tetrachlorosilane, to give a compound represented by Formula (b10).

Results obtained by instrumental analysis of the compound are shown below:

IR: 1590 (m), 1490 (m), 1430 (m), 1120 (m), and 700 (s) cm⁻¹ (Si-Ph) UV-Vis: 261 nm (Ph)

The measurement results above confirmed that the compound was the trichlorosilane-biphenyl-trimethoxysilane represented by Formula (b10).

The compound in the present Preparative Example was prepared in a similar manner to the second method described above.

### Experimental Example 7

### Preparative Example 10

### Preparation of Triethoxysilane-tetracene-tributoxysilane Represented by Formula (c6)

Two moles of metal magnesium and 300 ml of chloroform solution were placed in a 1-liter glass flask equipped with a stirrer, a reflux condenser, a thermometer, and a dropping funnel under dry argon stream; 0.5 mole of tetracene was added dropwise from the dropping funnel at around 10° C. over 12 hours; and, after dropwise addition, the mixture was aged at 15° C. for 4 hours, to give a Grignard reagent.

Two moles of tetrabutoxysilane and 300 ml of THF were placed in a 1-liter glass flask equipped with a stirrer, a reflux condenser, a thermometer, and a dropping funnel under dry argon stream; the Grignard reagent obtained was added dropwise over 2 hours at an internal temperature of 25° C. or lower; and, after dropwise addition, the mixture was aged at 30° C. for 1 hour. Then, the reaction solution was filtered under reduced pressure, for removal of magnesium chloride, and THF and unreacted tetrabutoxysilane were separated from the filtrate, to give tributoxysilane-tetracene.

Two moles of metal magnesium and 300 ml of toluene solution were placed in a flask equipped with a reflux condenser, a stirrer, a thermometer, and a dropping funnel under dry argon stream; the tributoxysilane-tetracene obtained was added dropwise from the dropping funnel while cooled to 0° C. over 12 hours; and, after dropwise addition, the mixture was aged at room temperature for 2 hours, to give an intermediate. A mixture of 2.0 moles of tetraethoxysilane and 300 ml of THF was added, and the intermediate cooled to 10° C. was added dropwise thereto over 8 hours. The mixture was stirred at 10° C. for 4 hours, warmed to room temperature, and stirred additionally for 2 hours. After stirring, the mixture was hydrolyzed, and the organic layer was separated, washed with water, and dried over magnesium sulfate. The solvent was distilled off, and the residue was fractionated by silica gel column chromatography, to give the compound represented by Formula (c6).

Results obtained by instrumental analysis of the compound are shown below:

¹H NMR (δ CDCl₃): 2.20 ppm (m, C₂ H₅) UV-Vis: 400-500 nm (tetracene p band), 265 nm (tetracene β band)

The measurement results confirmed that the compound was the triethoxysilane-tetracene-tributoxysilane represented by Formula (c6). It was also confirmed that it was possible to prepare such a silicon compound with other acene compound such as anthracene or pentacene as well as tetracene in the same manner.

The compound in the present Preparative Example was prepared in a similar manner to the first method described above.

### Experimental Example 8

### Preparative Example 11

### Preparation of n-trioctylsilane-quarterthiophene-triethoxysilane Represented by Formula (a13)

300 ml of THF and tetraethoxysilane were placed in a 1-liter glass flask equipped with a stirrer, a reflux condenser, a thermometer, and a dropping funnel under dry argon stream; the Grignard reagent obtained in a similar manner to Example 1 was added dropwise at an internal temperature of 0° C. or lower over 12 hours; and, after dropwise addition, the mixture was aged at room temperature for 4 hours, to give triethoxysilane-quarterthiophene.

Two moles of tetraoctylsilane and 300 ml of THF were placed and ice-cooed in a 1-liter glass flask equipped with a stirrer, a reflux condenser, a thermometer, and a dropping funnel under dry argon stream; the Grignard reagent was added dropwise over 2 hours at an internal temperature 25° C. or lower and, after dropwise addition, the mixture was aged at 30° C. for 1 hour. Then, the reaction solution was filtered under reduced pressure, removing the unreacted magnesium; THF and unreacted tetraoctylsilane were removed from the filtrate; and the solution was distilled off, to give the compound represented by Formula (a13).

Results obtained by instrumental analysis of the compound are shown below:

¹H NMR (δ CDCl₃): 7.63 to 7.78 (m, C₄H₂S) IR: 2966 and 2893 cm⁻¹ (S, C₂H₅) UV-Vis: 410 nm (toluene solution) (thiophene ring)

The results showed that the compound was n-trioctylsilane-quarterthiophene-triethoxysilane represented by Formula (a13).

### Experimental Example 9

### Preparative Example 12

It was confirmed that it was also possible to prepare trichlorosilane-quinquethiophene-triethoxysilane, trichlorosilane-hexithiophene-triethoxysilane, trichlorosilane-triphenyl-triethoxysilane, and trioctadecylsilane-terphenyl-trichlorosilane in a similar manner to Preparative Examples 8 and 9. It was also confirmed that it was possible to prepare silicon compounds, which have different functional groups at both terminals and contain octaphenylenes or octathiophenes having up to eight benzene or thiophene rings, in the same manner. It was also confirmed that it is rather difficult to obtain raw materials having nine or more bonded benzene or thiophene rings and thus the yield thereof declines.

### Experimental Example 10

### Preparative Example 13

### Preparation of n-trioctylsilane-dibenzoperylene-triethoxysilane Represented by Formula (a14)

Binaphthyl was prepared from naphthalene in reaction of naphthalene (Sigma-Aldrich Corporation) in a NaNO₂-TfOH (Tf=CF₃SO₂) solution. The binaphthyl was allowed to react with LITHF under oxygen bubbling, to give perylene. SbF₅ purchased from Sigma-Aldrich Corporation was diluted twice under dry argon atmosphere. SO₂ClF was prepared from SO₂Cl₂ generated in halogen exchange reaction between NH₄ F and TFA. Perylene was allowed to react with SbF₅ —SO₂ClF, and the products were purified by HPLC, to give dibenzoperylene. One equivalence of NCS with respect to dibenzoperylene was allowed to react with the dibenzoperylene in ACOH in the presence of CHCl₃, allowing chlorination. The product was then allowed to react with n-BuLi and trioctylsilane in THF solution, to give trioctylsilane-dibenzoperylene (yield: 8%).

Two moles of tetraethoxysilane and 300 ml of THF were placed and ice-cooled in a 1-liter glass flask equipped with a stirrer, a reflux condenser, a thermometer, and a dropping funnel under dry argon stream; the Grignard reagent was added dropwise at an internal temperature 25° C. or lower over 2 hours; and, after dropwise addition, the mixture was aged at 30° C. for 1 hour. Then, the reaction solution was filtered under reduced pressure, removing unreacted magnesium; THF and unreacted tetraethoxysilane were separated from the filtrate; and the solution was distilled off, to give the compound represented by Formula (a14).

Infrared absorption measurement of the compound obtained showed absorption at a wavelength of 1,050 nm corresponding to Si—O—C. The results confirmed that the compound obtained contained a silyl group.

Ultraviolet-visible absorption spectrum measurement of a chloroform solution containing the compound showed absorption at a wavelength of 378 nm. The absorption corresponds to π→π* transition of the dibenzoperylene skeleton contained in the molecule, indicating that the compound contained a dibenzoperylene skeleton.

Further, nuclear magnetic resonance (NMR) measurement of the compound was performed.

7.8 ppm (m) (5H, aromatic) 7.4 ppm (m) (2H, aromatic) 7.1 ppm (m) (2H, aromatic) 6.3 ppm (m) (2H, aromatic) 3.8 ppm (m) (6H, methylene group in ethoxy) 3.6 ppm (m) (2H, aromatic) 1.3 ppm (m) (9H, methyl group in ethoxy)

These results confirmed that the compound was n-trioctylsilane-dibenzoperylene-triethoxysilane.

Then, a chloroform solution of 0.2 mM n-trioctylsilane-dibenzoperylene-triethoxysilane represented by Formula (a14) was spread on the surface of water at pH 4 and a water temperature of 40° C., forming a pentalayer film as shown in FIG. 5(A) by the LB method, in which the layers are bound to each other via silanol bonds.

Observation of the film surface shape under an atomic force microscope (AFM) at a resolution of 50 μm in a similar manner to Example 1 revealed that the film was formed uniformly at the scale of 50 μm size. In addition, machining of the film by mechanical treatment showed that the film thickness was close to the sum of the molecular lengths, approximately 20 nm. The results above indicated that a pentalayer film uniform in film thickness was formed.

The crystal structure of the pentalayer film was evaluated, based on the electron beam diffraction (ED) measurement by a method similar to that in Example 1. The substrate used in the ED measurement was a Formval film vapor-deposited with SiO₂. As a result, diffraction spots corresponding to the dibenzoperylene crystal structures were observed with the pentalayer film.

### Example 8

### Preparation of Organic Thin-film Transistor and Evaluation of its Electrical Properties

The organic thin-film transistor shown in FIG. 9 was prepared.

First, chromium and gold were vapor-deposited on a silicon substrate 25, forming a gate electrode 24. Then, a gate insulation film 23 of silicon oxide film was formed thereon by chemical gas-phase adsorption. Further, chromium and gold were vapor-deposited through a mask, forming a source electrode 21 and a drain electrode 22.

The substrate with the electrodes was irradiated with ultraviolet light and thus, the surface of the gate insulation film 23 was hydrophilized. A pentalayer film of the monomolecular films of n-trioctylsilane-dibenzoperylene-triethoxysilane Formula (a14) was prepared in a similar manner to Example 3, except that the substrate obtained was used, to give the organic thin-film transistor shown in FIG. 9.

The field-effect mobility and the on/off ratio thereof were determined, for evaluation of the electrical properties of the transistor. The electric current flowing between the source and drain electrodes was measured, while changing the voltage applied thereto by varying the negative gate voltage (4155A; manufactured by Hewlett-Packard Company). As a result, the field-effect mobility was shown to be approximately 8×10⁻² cm²V⁻¹s⁻¹, and the on/off ratio was approximately a 5-digit number.

### Experimental Example 11

### Preparative Example 14

### Preparation of n-trichlorosilane-coronene-triethoxysilane Represented by Formula (a15)

The perylene obtained in Preparative Example 13 was converted into an anion in bromoacetaldehyde diethylacetal in reaction with an electrophilic agent and treated with molecular iodine, to give 1-perylene acetaldehyde diethylacetal and its isomer substituted at the 3 position. The 1 and 3-perylene acetaldehyde diethylacetals were dissolved in a mixed solution of conc. sulfuric acid and methanol, and the mixture was ultrasonicated for 1 hour, to give benzoperylene. The benzoperylene obtained was converted into the anion, treated with molecular iodine similarly, to give 5- and 7-benzoperylene acetaldehyde diethylacetals, and these benzoperylene derivatives were ultrasonicated and purified by recrystallization from toluene solvent, to give coronene. One equivalence of NCS with respect to coronene was allowed to react with coronene in AcOH in the presence of CHCl₃, allowing chlorination. The product was then allowed to react with n-BuLi and triethoxysilane in THF solution, to give triethoxysilane-coronene (yield: 46%).

Two moles of metal magnesium, 2.0 moles of tetrachlorosilane and 300 ml of tetrahydrofuran (THF) were placed in a 1-liter glass flask equipped with a stirrer, a reflux condenser, a thermometer, and a dropping funnel under dry argon stream; the triethoxysilane-coronene obtained was added dropwise at an internal temperature of 25° C. or lower over 2 hours; and, after dropwise addition, the mixture was aged at 30° C. for 1 hour. Then, the reaction solution was filtered under reduced pressure, for removal of magnesium chloride; THF and unreacted tetrachlorosilane were stripped off from the filtrate; and the solution was distilled, to give the compound represented by Formula (a14).

Infrared absorption measurement of the compound obtained showed absorption at a wavelength of 700 nm corresponding to Si—C, indicating that the compound obtained contained a silyl group.

Ultraviolet-visible absorption spectrum measurement of a chloroform solution containing the compound showed absorption at wavelengths of 338 and 300 nm. The absorption corresponds to π→π* transition of the coronene skeleton contained in the molecule, indicating that the compound contained a coronene skeleton.

Further, nuclear magnetic resonance (NMR) measurement of the compound was performed.

7.4 ppm (m) (11H, aromatic)

These results confirmed that the compound was trichlorosilane-coronene-triethoxysilane.

Then, a chloroform solution of 0.2 mM n-trichlorosilane-coronene-triethoxysilane represented by Formula (a15) was spread on the surface of water at pH 2 and a water temperature of 23° C., forming the pentalayer film as shown in FIG. 5(A) by the LB method in which the layers were bound to each other via silanol bonds.

Observation of the film surface shape under an atomic force microscope (AFM) at a resolution of 50 μm in a similar manner to Example 1 revealed that the film was formed uniformly at the scale of 50 μm. In addition, machining of the film by mechanical treatment showed that the film thickness was close to the sum of the molecular lengths, approximately 22 nm. The results above indicated that a heptalayer film uniform in film thickness was formed.

The crystal structure of the heptalayer film was evaluated, based on the electron beam diffraction (ED) measurement by a method similar to that in Example 1. The substrate used in the ED measurement was a Formval film vapor-deposited with SiO₂. As a result, diffraction spots corresponding to the dibenzoperylene crystal structures were observed with the pentalayer film.

### Example 9

### Preparation of Organic Thin-film Transistor and Evaluation of its Electrical Properties

The organic thin-film transistor shown in FIG. 9 was prepared.

First, chromium and gold were vapor-deposited on a silicon substrate 25, forming a gate electrode 24. Then, a gate insulation film 23 of silicon oxide film was formed thereon by chemical gas-phase adsorption. Further, chromium and gold were vapor-deposited through a mask, forming a source electrode 21 and a drain electrode 22.

The substrate with the electrodes was irradiated with ultraviolet light and the surface of the gate insulation film 23 was hydrophilized. A heptalayer film of n-trichlorosilane-coronene-triethoxysilane Formula (a15) monomolecular films was prepared in a similar manner to Example 3, except that the substrate obtained was used, to give the organic thin-film transistor as shown in FIG. 9.

The field-effect mobility and the on/off ratio thereof were determined, for evaluation of the electrical properties of the transistor. The electric current flowing between the source and drain electrodes was measured, while changing the voltage applied thereto by varying the negative gate voltage (4155A; manufactured by Hewlett-Packard Company). As a result, the field-effect mobility was shown to be approximately 7×10⁻² cm²V⁻¹s⁻¹, and the on/off ratio was approximately a 6-digit number.

What is claimed is:

1. An organic compound represented by General Formula (I): 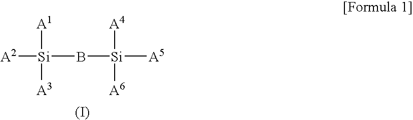
(wherein, A¹ to A⁶ each independently represent a hydrogen atom, a halogen atom, an alkoxy group having 1 to 10 carbon atoms, or an alkyl group having 1 to 18 carbon atoms; A¹ to A⁶ satisfy the relationship in elimination reactivity of A¹ to A³>A⁴ to A⁶; and B represents a bivalent organic group).

2. The organic compound according to claim 1, wherein the organic group B represents a π-electron-conjugated bivalent organic group.

3. The organic compound according to claim 2, wherein the organic group B represents a group derived from a monocyclic aromatic compound, a condensed aromatic compound, a monocyclic heterocyclic compound, a condensed heterocyclic compound, an unsaturated aliphatic compound, or a compound having two to eight of the compounds above bound to each other.

4. The organic compound according to claim 2, wherein the organic group B is a group derived from a monocyclic aromatic compound, a monocyclic heterocyclic compound, a compound having two to eight of the compounds above bound to each other or a condensed aromatic compound.

5. The organic compound according to claim 2, wherein the combinations of A¹ to A³ and A⁴ to A⁶ are shown by any one of the followings (1) to (4):
(1) A¹ to A³ each independently represent a halogen atom and A⁴ to A⁶ each independently represent an alkoxy group;
(2) A¹ to A³ each independently represent a halogen atom and A⁴ to A⁶ each independently represent an alkyl group;
(3) A¹ to A³ each independently represent an alkoxy group having 1 to 2 carbon atoms and A⁴ to A⁶ each independently represent an alkoxy group having 3 to 4 carbon atoms; and
(4) A¹ to A³ each independently represent an alkoxy group having 1 to 2 carbon atoms and A⁴ to A⁶ each independently represent an alkyl group having 3 to 4 carbon atoms.

6. A method of producing the organic compound according to claim 1, comprising:
allowing a compound represented by (Formula):
H—B—MgX (2)
(wherein, B represents a bivalent organic group; and X represents a halogen atom) to react with a compound represented by (Formula)
Y¹—Si(A¹)(A²)(A³) (3)
(wherein, Y¹ represents a halogen atom; and A¹ to A³ each independently represent a hydrogen atom, a halogen atom, an alkoxy group having 1 to 10 carbon atoms, or an alkyl group having 1 to 18 carbon atoms) in order to form a compound represented by (Formula):
H—B—Si(A¹)(A²)(A³) (4);
preparing a compound represented by (Formula)
MgX—B—Si(A¹)(A²)(A³) (5)
by binding a halogen atom to the B group in the compound shown in Formula (4) and allowing the halogenated compound to react with magnesium or lithium metal in the presence of ethoxyethane or tetrahydrofuran (THF); and
allowing the product to react with a compound represented by (Formula)
Y²—Si(A⁴)(A⁵)(A⁶) (6)
(wherein, Y² represents a halogen atom; and A⁴ to A⁶ each independently represent a hydrogen atom, a halogen atom, an alkoxy group having 1 to 10 carbon atoms, or an alkyl group having 1 to 18 carbon atoms, and satisfy the relationship in elimination reactivity of A¹ to A³>A⁴ to A⁶).

7. A method of producing an organic compound according to claim 1 organic compound, comprising:
forming a Grignard reagent from a compound represented by (Formula):
X¹—B—X² (8)
(wherein, B represents a bivalent organic group; and X¹ and X² each differently represents a halogen atom.) by using a metal catalyst of magnesium or lithium;
allowing the product to react with a compound represented by (Formula)
Y¹—Si(A¹)(A²)(A³) (3)
(wherein, Y¹ represents a halogen atom, and A¹ to A³ each independently represent a hydrogen atom, a halogen atom, an alkoxy group having 1 to 10 carbon atoms, or an alkyl group having 1 to 18 carbon atoms) in order to prepare a Grignard reagent represented by the following formula:
Si(A¹)(A²)(A³)-B—MgX² (9); and then
allowing a compound represented by (Formula)
Y²—Si(A⁴)(A⁵)(A⁶) (6)
(wherein, Y² represents a halogen atom, and A⁴ to A⁶ each independently represent a hydrogen atom, a halogen atom, an alkoxy group having 1 to 10 carbon atoms, or an alkyl group having 1 to 18 carbon atoms and satisfy the relationship in elimination reactivity of A¹ to A³>A⁴ to A⁶) to react with the compound represented by (Formula 9).

8. An organic thin film, formed by using the organic compound according to claim 2.

9. The organic thin film according to claim 8 having a multilayer unimolecular film structure, wherein first to n'th monomolecular films (n is an integer of 2 or more) are formed in that order on substrate, and at least the first to (n−1)'th monomolecular films are formed with the organic compound represented by General Formula (I).

10. The organic thin film according to claim 8, wherein the organic compound molecule in the monomolecular film formed by using the organic compound represented by General Formula (I) is oriented in such a way that the silyl group having A¹ to A³ is oriented to the substrate side and the silyl group having A⁴ to A⁶ to the film surface side.

11. The organic thin film according to claim 9, wherein the first monomolecular film is bound to the substrate by the silyl groups having A¹ to A³ and to the second monomolecular film by the silyl group having A⁴ to A⁶.

12. The organic thin film according to claim 9 having a multilayer unimolecular film structure, wherein first to n'th monomolecular films (n is an integer of 3 or more) are formed in that order on substrate, and the second to (n−1)'th monomolecular films are bound respectively to the monomolecular films immediately below by the silyl groups having A¹ to A³ and to the monomolecular films immediately above by the silyl groups having A⁴ to A⁶.

13. A method of producing an organic thin film having a multilayer unimolecular film structure, comprising;
(1) a step of forming a single monomolecular film having a monomolecular layer directly adsorbed to a substrate by allowing the silyl group having A¹ to A³ in the organic compound according to claim 2 to react with the substrate surface;
(2) a step of removing unreacted organic compounds by using a non-aqueous solvent; and
(3) a step of forming an additional monomolecular film of the organic compound according to claim 2 by using the unreacted silyl groups, which are present on the film surface side of the monomolecular film obtained, as the sites for adsorption reaction.

14. The method of producing an organic thin film according to claim 13, wherein, in step (1), the substrate is an elemental conductor material, a compound semiconductor material, quartz glass or a polymeric material, and hydroxyl groups are protruded on the substrate by hydrophilizing treatment and the hydroxyl groups are allowed to react with the silyl groups having A¹ to A³ to form a single monomolecular film having a monomolecular layer directly adsorbed to the substrate.

15. The method of producing an organic thin film according to claim 13, wherein the reaction of the silyl group having A¹ to A³ in the organic compound according to claim 2 with the substrate in step (1), and the adsorption reaction onto the unreacted silyl group in step (3) are controlled by adjustment of the solvent atmosphere and the reaction temperature.

16. An organic device, comprising the organic thin film according to claim 8.

17. The organic device according to claim 16, wherein the organic device is an organic thin-film transistor at least having a substrate, a gate electrode formed on the substrate, an gate insulation film formed on the gate electrode, and a source electrode, a drain electrode and a semiconductor layer formed in contact with or separated from the gate insulation film, and the semiconductor layer is an organic thin film formed by using the organic compound represented by General Formula (I).

18. The organic device according to claim 16, wherein the organic device is an organic photoelectric conversion element at least having an organic layer formed between a transparent electrode and a counter electrode and the organic layer is an organic thin film formed by using the organic compound represented by General Formula (I).

19. The organic device according to claim 16, wherein the organic device is an organic EL element at least having an organic layer between an anode and a cathode and the organic layer is an organic thin film formed by using the organic compound represented by General Formula (I).

20. A method of producing an organic device, comprising forming an organic thin film by the method according to claim 13.
